(19) United States
(12) Patent Application Publication
(10) Pub. No.: US 2025/0176289 A1
(43) Pub. Date: May 29, 2025

(54) SOLID-STATE IMAGING DEVICE, IMAGING SYSTEM, AND IMAGING PROCESSING METHOD

(71) Applicant: Sony Semiconductor Solutions Corporation, Kanagawa (JP)

(72) Inventors: Katsuji Kimura, Kanagawa (JP); Daichi Murakami, Tokyo (JP)

(21) Appl. No.: 18/692,130

(22) PCT Filed: Sep. 15, 2022
(86) PCT No.: PCT/JP2022/034642

§ 371 Date: Aug. 23, 2024

(30) Foreign Application Priority Data
Nov. 8, 2021 (JP) 2021-182003

(51) Int. Cl. H10F 39/00; H04N 23/68; H10F 39/12

(52) U.S. Cl. CPC H10F 39/8063; H04N 23/687; H10F 39/193; H10F 39/8053; H10F 39/8057

(57) ABSTRACT

Solid-state imaging with simultaneously capture of images in infrared and visible light is disclosed. In one example, a solid-state imaging device includes a lens optical system, first and second photoelectric conversion units, and a storage unit. The first photoelectric conversion unit detects visible light. The second photoelectric conversion unit is aligned with the first photoelectric conversion unit and detects infrared light. The storage unit stores an amount of aberration at a focal point between the visible light and the infrared light. After focusing on a focal point of light in a second wavelength range detected by the second photoelectric conversion unit, the solid-state imaging device compensates for the aberration at a focal point between the visible light and the infrared light on the basis of the amount of aberration.

### TECHNICAL FIELD

The technology (present technology) according to the present disclosure relates to a solid-state imaging device, an imaging system, and an imaging processing method.

### BACKGROUND ART

Recent imaging devices are becoming increasingly higher in pixel count, higher in performance, and smaller in size. Such an increase in pixel count and an increase in performance of the imaging devices leads to an increase in functionality of a charge-coupled device (CCD) sensor, a complementary metal-oxide-semiconductor (CMOS) image sensor, or the like mounted on the imaging devices.

In such an imaging device, a CMOS image sensor having a sensing function, that is, a function of photoelectrically converting IR light (hereinafter, referred to as IR) of a wavelength in the infrared wavelength range, such as a wavelength of 840 nm or 940 nm, for measuring a length with auxiliary light for lens focusing using infrared light or for three-dimensional (3D) sensing of a subject in accordance with visible light, that is, red (R), green (G), and blue (B) light wavelengths (hereinafter, visible light) has been proposed for a solid-state imaging element as one of performance improvements.

As disclosed in Patent Document 1 and Patent Document 4, proposed is the above-described solid-state imaging element that includes a layer that captures an image of RGB visible light and a layer that captures an image of IR light so as to be capable of simultaneously capturing the image of visible light and the image of IR light. A structure disclosed in Patent Document 4 is similar to a structure disclosed in Patent Document 1, but has a configuration where one infrared light imaging element is provided for a plurality of visible light imaging elements instead of a configuration including visible light (R, G, B) and infrared light (IR) pixels.

However, in a case where attention is paid to optical characteristics of the solid-state imaging element, there is a problem that the focus position becomes misaligned between the visible light layer and the IR light layer of the solid-state imaging element due to the influence of lens aberration, particularly axial chromatic aberration.

In order to solve the focus position misalignment described above, the solid-state imaging element includes a dual-bandpass filter (DBPF) or the like that cuts off light other than visible light and IR light between the lens and the solid-state imaging element, and, for example, a structure disclosed in Patent Document 2 where the dual-bandpass filter described above is changed in thickness so as to switch optical path lengths of visible light and IR light at the time of imaging copes with the problem of the focus position misalignment.

The method disclosed in Patent Document 1, however, requires a combination of two DBPFs, which leads to an increase in DBPF thickness, that is, an increase in height of the solid-state imaging element. Furthermore, in order to mechanically operate the two DBPFs, a driving unit is required, which leads to an increase in cost. Solid-state imaging devices included in recent mobile devices, wearable devices, and the like are becoming increasingly smaller in size, height, and cost, which poses a challenge to Patent Document 1.

As a solution for Patent Document 1 described above, Patent Document 2 proposes a configuration where, for compensation for axial chromatic aberration caused by the lens described above, a memory is provided in a solid-state imaging element, the memory is read by a CPU every time a camera is activated, and the lens is driven at the time of imaging to compensate for a difference in aberration between visible light and IR light.

Furthermore, in the technology disclosed in Patent Document 3, the amount of axial chromatic aberration between visible light and infrared light is stored in an external storage device, the amount of axial chromatic aberration is read from the external storage device, distance measurement is performed with infrared light, and the lens is driven at the time of capturing an image of visible light.

As another method of autofocusing and imaging, a method has been proposed in which a hologram is irradiated with a laser light source to assist autofocusing (for example, Patent Document 5).

### CITATION LIST

### Patent Document

Patent Document 1: Japanese Patent Application Laid-Open No. 2017-208496
Patent Document 2: Japanese Patent Application Laid-Open No. 2001-272708
Patent Document 3: Japanese Patent Application Laid-Open No. 2002-182105
Patent Document 4: WO 2020/255999
Patent Document 5: Japanese Patent Application Laid-Open No. 2002-237990

### SUMMARY OF THE INVENTION

### Problems to be Solved by the Invention

In Patent Document 2, however, separate imaging elements are provided for visible light and infrared light, so that the cost becomes higher, and alignment between the two sensors for aberration compensation in an imaging plane of visible light becomes very complicated, which makes manufacturing complicated and higher in cost.

Furthermore, in the method disclosed in Patent Document 3, the external storage device is required, and a solid-state imaging element that captures an image of infrared light is separately provided, which leads to an increase in cost.

Moreover, in the method disclosed in Patent Document 5, axial chromatic aberration may occur as a problem in a case of infrared light. Furthermore, in a case where the laser light source is a light source close to the red wavelength of visible light, there is a problem that measurement of a distance to a subject and capturing of an image of RGB cannot be performed at the same time.

The present disclosure has been made in view of such circumstances, and it is therefore an object of the present disclosure to provide a solid-state imaging device, an imaging system, and an imaging processing method that allow simultaneous capturing of an image of infrared light and an image of visible light and allow an increase in performance, a reduction in size, and a reduction in cost.

### Solutions to Problems

An aspect of the present disclosure is a solid-state imaging device including: a lens optical system; a first photoelectric conversion unit including a plurality of first photoelectric conversion elements provided in a matrix pattern, the plurality of first photoelectric conversion elements being configured to detect light in a first wavelength range including visible light reflected off a subject and perform photoelectric conversion; a second photoelectric conversion unit provided at a position aligned with the first photoelectric conversion unit and including a plurality of second photoelectric conversion elements provided in a matrix pattern, the plurality of second photoelectric conversion elements being configured to detect light in a second wavelength range including infrared light reflected off the subject and perform photoelectric conversion; and a storage unit configured to store an amount of aberration at a focal point between the light in the first wavelength range and the light in the second wavelength range in the lens optical system, in which the aberration at a focal point between the light in the first wavelength range and the light in the second wavelength range is compensated for on the basis of the amount of aberration stored in the storage unit after focusing on a focal point of the light in the second wavelength range detected by the second photoelectric conversion unit.

Another aspect of the present disclosure is an imaging system including: an irradiation unit configured to emit infrared light to a subject; and an imaging element configured to receive light reflected off the subject, in which the imaging element includes: a lens optical system; a first photoelectric conversion unit including a plurality of first photoelectric conversion elements provided in a matrix pattern, the plurality of first photoelectric conversion elements being configured to detect light in a first wavelength range including visible light reflected off the subject and perform photoelectric conversion; a second photoelectric conversion unit provided at a position aligned with the first photoelectric conversion unit and including a plurality of second photoelectric conversion elements provided in a matrix pattern, the plurality of second photoelectric conversion elements being configured to detect light in a second wavelength range including infrared light reflected off the subject and perform photoelectric conversion; and a storage unit configured to store an amount of aberration at a focal point between the light in the first wavelength range and the light in the second wavelength range in the lens optical system, and the imaging element compensates for the aberration at a focal point between the light in the first wavelength range and the light in the second wavelength range on the basis of the amount of aberration stored in the storage unit after focusing on a focal point of the light in the second wavelength range detected by the second photoelectric conversion unit.

Furthermore, another aspect of the present disclosure is an imaging processing method including: causing an irradiation unit to emit infrared light to a subject; causing a signal processing unit to drive a lens optical system relative to the subject on the basis of light reflected off the subject to focus on a focal point of light in a first wavelength range including the infrared light; and causing the signal processing unit to read an amount of aberration stored in a storage unit on the basis of a result of focusing on the focal point of the light in the first wavelength range and compensate for aberration at a focal point between light in a second wavelength range including visible light and the light in the first wavelength range on the basis of the amount of aberration.

### BRIEF DESCRIPTION OF DRAWINGS

FIG. 1 is a schematic configuration diagram depicting an example of a configuration of a sensor system to which an imaging system according to a first embodiment of the present disclosure is applied.

FIG. 2 depicts an example of filter transmission characteristics when a wavelength of a laser light source according to the first embodiment of the present disclosure has 940 nm characteristics.

FIG. 3 is a diagram depicting an example of a configuration of an imaging element according to the first embodiment of the present disclosure.

FIG. 4 is a partial longitudinal cross-sectional view depicting an example of a cross-sectional structure of a semiconductor substrate of the imaging element according to the first embodiment of the present disclosure.

FIG. 5 depicts an example where infrared light is output from the laser light source according to the first embodiment of the present disclosure in a pattern of six dots for X and four dots for Y, an angle of view is adjusted by a compensation lens, and the infrared light is applied to a subject.

FIG. 6 depicts separate blocks corresponding to functions of the imaging element according to the first embodiment of the present disclosure.

FIG. 7 is a diagram for describing respective focal points of visible light and infrared light by a lens.

FIG. 8 depicts an example of a graph showing a result of optical simulation of a focal position with the imaging element according to the first embodiment of the present disclosure as a target and a lens.

FIG. 9 is a characteristic diagram depicting a depth of focus for the size of the imaging element and the size of a circle required for lens resolution.

FIG. 10 is a characteristic diagram depicting a depth of focus for the size of the imaging element and the size of a circle required for lens resolution.

FIG. 11 is a flowchart depicting an example of a procedure of processing performed by an application processor responsible for autofocusing and imaging in the imaging element according to the first embodiment of the present disclosure.

FIG. 12 is a flowchart depicting an example of a procedure of processing performed by an application processor responsible for autofocusing and imaging in an imaging element according to a first modification of the first embodiment of the present disclosure.

FIG. 13 is a flowchart depicting an example of a procedure of processing performed by an application processor responsible for autofocusing and imaging in an imaging element according to a second modification of the first embodiment of the present disclosure.

FIG. 14 is a partial longitudinal cross-sectional view depicting an example of a cross-sectional structure of a semiconductor substrate of an imaging element according to a second embodiment of the present disclosure.

FIG. 15 is a partial longitudinal cross-sectional view depicting an example of a cross-sectional structure of a semiconductor substrate of an imaging element according to a third embodiment of the present disclosure.

FIG. 16 is a partial longitudinal cross-sectional view depicting an example of a cross-sectional structure of a semiconductor substrate of an imaging element according to a fourth embodiment of the present disclosure.

FIG. 17 depicts an example of how an imaging element 1 according to a fifth embodiment of the present disclosure outputs data.

FIG. 18A is a schematic diagram depicting an example of an overall configuration of a photodetection system according to a sixth embodiment of the present disclosure.

FIG. 18B is a schematic diagram depicting an example of a circuit configuration of the photodetection system according to the sixth embodiment of the present disclosure.

FIG. 19 is a block diagram depicting a configuration example of an electronic device to which the present technology is applied.

FIG. 20 is a view depicting an example of a schematic configuration of an endoscopic surgery system.

FIG. 21 is a block diagram depicting an example of a functional configuration of a camera head and a camera control unit (CCU).

FIG. 22 is a block diagram depicting an example of a schematic configuration of a vehicle control system.

FIG. 23 is a diagram of assistance in explaining an example of installation positions of an outside-vehicle information detecting section and an imaging section.

### MODE FOR CARRYING OUT THE INVENTION

The following is a description of embodiments of the present disclosure given with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the proportion of thickness of each device or each member, and the like differ from actual ones. Therefore, specific thicknesses and dimensions should be determined in consideration of the following description. Furthermore, it goes without saying that dimensional relationships and ratios are partly different between the drawings.

Furthermore, definition of directions such as upward and downward directions, and the like in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

Note that the effects described in the present specification are merely examples and are not limited, and other effects may be provided.

### First Embodiment

### (Configuration of Sensor System)

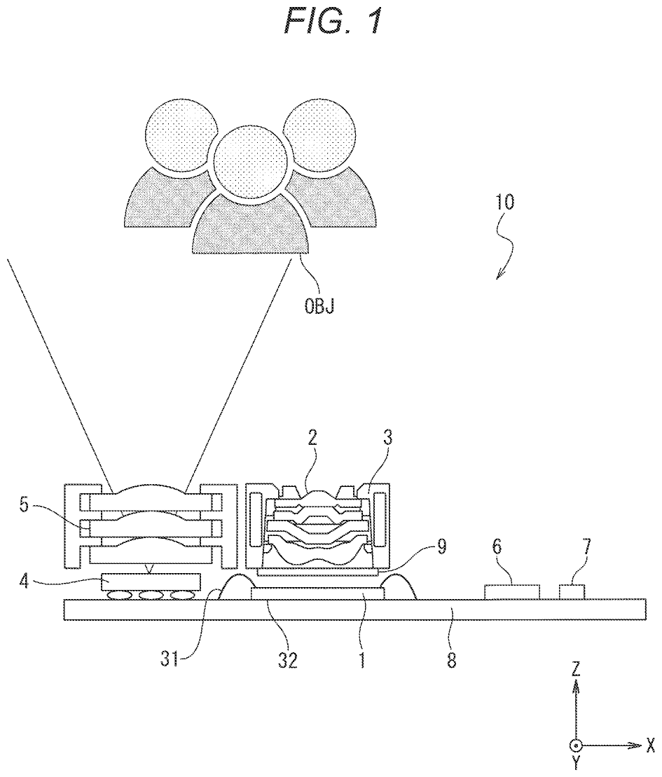

FIG. 1 is a schematic configuration diagram depicting an example of a configuration of a sensor system to which an imaging system according to a first embodiment of the present disclosure is applied.

A sensor system 10 according to the first embodiment is applicable to an imaging device including an imaging element such as a charge-coupled device (CCD) sensor or a complementary metal-oxide-semiconductor (CMOS) image sensor. Furthermore, the sensor system 10 is further applicable to a device including such an imaging device, for example, a mobile terminal device.

The sensor system 10 includes an imaging element 1, a lens 2, an actuator 3, a laser light source 4, and a compensation lens 5. Note that the sensor system 10 may include at least the imaging element 1 and the laser light source 4. In this case, the lens 2, the actuator 3, and the compensation lens 5 can be externally connected to the sensor system 10.

The laser light source 4 emits infrared light used for measuring a distance to a subject OBJ or for biometric authentication. The laser light source 4 includes the compensation lens 5 for the purpose of appropriately emitting light to the subject OBJ. Furthermore, instead of the compensation lens 5, an optical diffraction element (hereinafter, referred to as DOE) used for ToF, structured light, or the like may be provided. The present disclosure is applicable to any dot or pattern obtained by correcting light output from the laser light source 4 and emitting the light to the subject OBJ without depending on a shape of the emitted light.

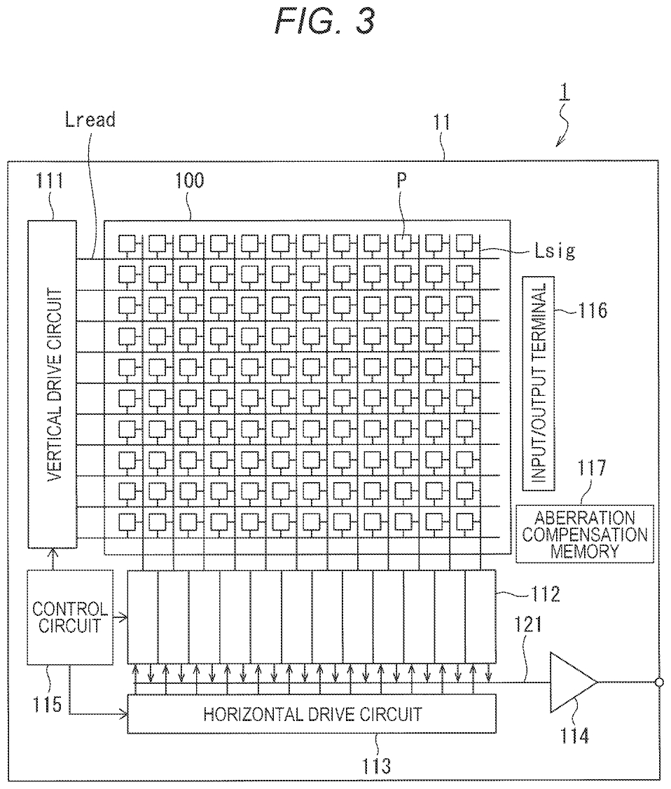

The lens 2 condenses light from the subject OBJ on the imaging element 1 to form an image on a pixel unit 100 (illustrated in FIG. 3) of the imaging element 1. The imaging element 1 is a CCD sensor, a CMOS image sensor, or the like that photoelectrically converts the light from the subject OBJ to capture an image, and has a function of receiving visible light and infrared light in accordance with their respective wavelengths. Although not illustrated in detail, the present disclosure is also useful in an imaging element having a configuration where an R, G, B filter, called Bayer arrangement, is partially replaced with an R, G, B, W (white) filter.

In general, the laser light source 4 uses infrared light of a wavelength in 850 nm, 940 nm, and 1300 nm ranges with a relatively small solar spectrum; however, changing characteristics of a dual-bandpass filter (DBPF) 9 to be described later makes it possible to adapt to any wavelength. In the present disclosure, it can be used without depending on the infrared wavelength.

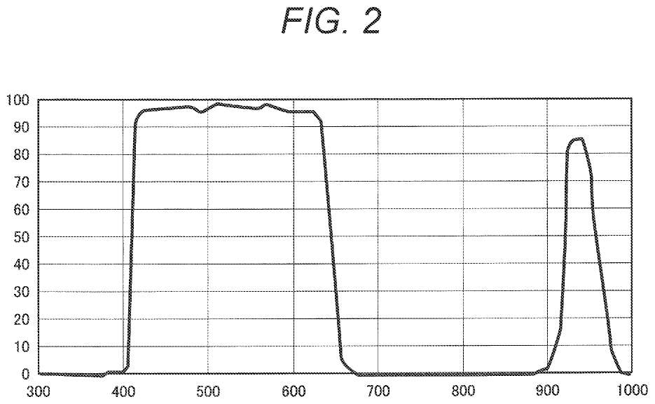

The dual-bandpass filter (DBPF) 9 is disposed between the imaging element 1 and the lens 2 so as to allow efficient capturing of an image of visible light (R, G, B) and an image of infrared light (IR). FIG. 2 depicts an example of filter transmission characteristics when a wavelength of the laser light source 4 has 940 nm characteristics. As described above, the characteristics of the DBPF 9 can be changed in accordance with the wavelength of the laser light source 4.

Furthermore, the sensor system 10 includes the actuator 3 that drives the lens 2 upward or downward (hereinafter, referred to as Z-axis direction) relative to the imaging element 1 in order to focus the lens 2. The lens 2 is integrated with a holder on which a coil for driving in the Z-axis direction is mounted.

Furthermore, the actuator 3 also has a function of performing compensation to reduce the influence of camera shake by being driven in a direction (hereinafter, appropriately referred to as X-axis direction or Y-axis direction) of a plane (hereinafter, appropriately referred to as XY plane) horizontal to the imaging surface of the imaging element 1.

Furthermore, the sensor system 10 includes a gyro sensor 7 for image stabilization, an autofocus/optical image stabilizer (OIS) driver LSI 6 for externally controlling the actuator 3, and a circuit board 8 for outputting an electric signal of the imaging element 1 to the outside. Note that, although the circuit board is described here, the circuit board need not necessarily be a plate-like board and may be a circuit substrate.

The OIS means optical image stabilization, and is a mechanism for compensating for camera shake in an optical system. In the optical image stabilization, the gyro sensor 7 senses vibrations at the time of imaging, and adjusts the position of the lens 2 or adjusts the position of the imaging element 1 to compensate for camera shake. Herein, the image stabilization is performed by adjusting the position of the lens 2.

The sensor system 10 includes a metal wire 31 for electrically connecting the imaging element 1 and the circuit board 8, and includes an adhesive 32 for fixing the imaging element 1 and the circuit board 8 together.

### (Configuration of Imaging Element)

FIG. 3 is a diagram depicting an example of a configuration of the imaging element 1 described above. The imaging element 1 is, for example, a complementary metal oxide semiconductor (CMOS) image sensor. The imaging element 1 receives incident light (image light) from a subject through, for example, an optical lens system, converts the incident light, an image of which is formed on the imaging surface, to an electric signal on a pixel-by-pixel basis, and output the electric signal as a pixel signal. The imaging element 1 can be integrally configured as, for example, a system on a chip (SoC) such as a CMOS LSI, but for example, some components described below may be configured as separate LSIs. In the present disclosure, the imaging element 1 is a so-called back-illuminated solid-state imaging element. In the back-illuminated solid-state imaging element, a surface of a semiconductor substrate 11 on which external light is incident is referred to as “back surface”, and a surface on an opposite side is referred to as “front surface”. The imaging element 1 includes, for example, on the semiconductor substrate 11, a pixel unit 100 as an imaging area, and a vertical drive circuit 111, a column signal processing circuit 112, a horizontal drive circuit 113, an output circuit 114, a control circuit 115, and an input/output terminal 116 arranged around the pixel unit 100.

The pixel unit 100 includes, for example, a plurality of pixels P two-dimensionally arranged in a matrix pattern. The pixel unit 100 is provided with, for example, a plurality of pixel rows including a plurality of pixels P arranged in a row direction (lateral direction in the plane of drawing) and a plurality of pixel columns including a plurality of pixels P arranged in a column direction (longitudinal direction in the plane of drawing). A region occupied by the plurality of pixels P arranged in a matrix pattern serves as a so-called “image height” corresponding to a target space to be imaged. In the pixel unit 100, for example, one pixel drive line Lread (row selection line and reset control line) is laid for each pixel row, and one vertical signal line Lsig is laid for each pixel column. The pixel drive line Lread transmits a drive signal for reading a signal from each pixel P. The plurality of pixel drive lines Lread has their respective ends connected to a plurality of output terminals of the vertical drive circuit 111 corresponding to the pixel rows.

The vertical drive circuit 111 includes a shift register, an address decoder, and the like, and serves as a pixel driving unit that drives each pixel P in the pixel unit 100, for example, on a pixel row-by-pixel row basis. The signal output from each pixel P of a pixel row selectively scanned by the vertical drive circuit 111 is supplied to the column signal processing circuit 112 through a corresponding one of the vertical signal lines Lsig.

The column signal processing circuit 112 includes an amplifier, a horizontal selection switch, and the like provided for each vertical signal line Lsig.

The horizontal drive circuit 113 includes a shift register, an address decoder, and the like, and sequentially drives the horizontal selection switches of the column signal processing circuit 112 while scanning the horizontal selection switches. The selective scanning by the horizontal drive circuit 113 causes the signal from each pixel P transmitted through a corresponding one of the plurality of vertical signal lines Lsig to be sequentially output to the horizontal signal line 121 and transmitted to the outside of the semiconductor substrate 11 through the horizontal signal line 121.

The output circuit 114 is configured to perform signal processing on the signal sequentially supplied from each column signal processing circuit 112 through the horizontal signal line 121 and output the resultant signal. There is a case where the output circuit 114 performs only buffering, for example, or a case where the output circuit 114 performs black level adjustment, column variation correction, various types of digital signal processing, and the like.

Circuit portions including the vertical drive circuit 111, the column signal processing circuit 112, the horizontal drive circuit 113, the horizontal signal line 121, and the output circuit 114 may be provided directly on the semiconductor substrate 11, or may be arranged in an external control IC. Furthermore, such circuit portions may be provided on another substrate connected by a cable or the like.

The control circuit 115 receives clocks supplied from the outside of the semiconductor substrate 11, data indicating an operation mode, and the like, and outputs data such as internal information of the pixels P that are imaging elements. The control circuit 115 further includes a timing generator that generates various timing signals, and performs drive control on the peripheral circuits such as the vertical drive circuit 111, the column signal processing circuit 112, the horizontal drive circuit 113, and the like on the basis of the various timing signals generated by the timing generator.

Furthermore, the imaging element 1 of the present disclosure includes an aberration compensation memory 117 that stores information (amount) of aberration at a focal point between visible light and infrared light by the lens 2. The amount of aberration stored in the aberration compensation memory 117 is read by an external application processor (details will be described later) and used for compensating for aberration at a focal point between visible light and infrared light.

### (Cross-Sectional Structure of Imaging Element)

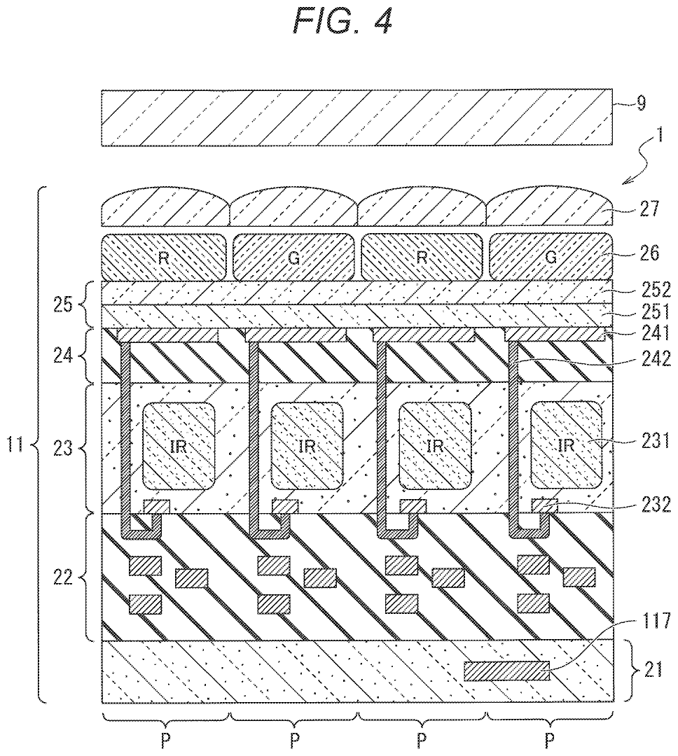

FIG. 4 is a partial longitudinal cross-sectional view depicting an example of a cross-sectional structure of the semiconductor substrate 11 of the imaging element 1 according to the first embodiment of the present disclosure. As depicted in the drawing, the semiconductor substrate 11 roughly includes, for example, a semiconductor support substrate 21, a wiring layer 22, an IR photoelectric conversion layer 23, an intermediate layer 24, an organic photoelectric conversion layer 25, a color filter 26, and on-chip lenses 27.

The on-chip lens 27 is an optical lens for efficiently condensing light incident on the imaging element 1 from the outside through the DBPF 9 to form an image on each pixel P (that is, an IR photoelectric conversion element 231 and organic photoelectric conversion elements 251 and 252) of the IR photoelectric conversion layer 23 and the organic photoelectric conversion layer 25. The on-chip lens 27 is typically arranged for each pixel P. Note that the on-chip lens 27 includes, for example, silicon oxide, silicon nitride, silicon oxynitride, organic SOG, polyimide resin, fluorine resin, or the like.

The color filter 26 is an optical filter that selectively transmits light of a predetermined wavelength of the light condensed by the on-chip lens 27. In this example, two color filters 26 that selectively transmit light of wavelengths of red light (R) and green light (G) are used, but such a configuration is not construed as limiting the present disclosure. In each pixel P, a color filter 26 corresponding to any color (wavelength) of red light, green light, blue light, or infrared light is arranged.

The organic photoelectric conversion layer 25 is a functional layer in which the organic photoelectric conversion elements 251 and 252 are provided, the organic photoelectric conversion elements 251 and 252 being components of each pixel P. The organic photoelectric conversion layer 25 includes the organic photoelectric conversion element 251 sensitive to green light (G) and the organic photoelectric conversion element 252 sensitive to red light (R) stacked in this order. The organic photoelectric conversion element 251 detects green light (G), performs photoelectric conversion, and outputs the conversion result as a pixel signal. The organic photoelectric conversion element 252 detects red light (R), performs photoelectric conversion, and outputs the conversion result as a pixel signal. Note that part of the light (for example, infrared light) incident on an incident surface of the organic photoelectric conversion layer 25 can transmit a surface (that is, the front surface) opposite to the incident surface (that is, the back surface).

The intermediate layer 24 is a layer in which an electrode 241 and a wiring 242 for transmitting power and various drive signals to each pixel P in the organic photoelectric conversion layer 25 and transmitting the pixel signal read from each pixel P are provided.

The IR photoelectric conversion layer 23 is a functional layer in which a pixel circuit group including the IR photoelectric conversion element 231 and electronic elements such as various transistors are provided, the IR photoelectric conversion element 231 and the electronic elements being components of each pixel P. The IR photoelectric conversion element 231 of the IR photoelectric conversion layer 23 detects infrared light (IR) incident through the on-chip lens 27 and the color filter 26, performs photoelectric conversion, and outputs the conversion result as a pixel signal. The IR photoelectric conversion element 231 and the various electronic elements are electrically connected to the electrode 241 of the intermediate layer 24 via an electrode 232 and the wiring 242, and are electrically connected to a predetermined metal wiring in the wiring layer 22.

The wiring layer 22 is a layer in which a metal wiring pattern for transmitting power and various drive signals to each pixel P in the IR photoelectric conversion layer 23 and the organic photoelectric conversion layer 25 or transmitting the pixel signal read from each pixel P is provided. In this example, the wiring layer 22 is provided on the semiconductor support substrate 21. The wiring layer 22 can typically include a plurality of layers of metal wiring patterns stacked together with an interlayer insulating film interposed therebetween. Furthermore, the stacked metal wiring patterns are electrically connected via, for example, vias, as necessary. The wiring layer 22 includes, for example, metal such as aluminum (Al) or copper (Cu). On the other hand, the interlayer insulating film includes, for example, silicon oxide or the like.

The semiconductor support substrate 21 is a substrate for supporting various layers formed in a semiconductor manufacturing process. Furthermore, in the semiconductor support substrate 21, for example, a logic circuit by which some of the various components described above are implemented and the aberration compensation memory 117 are provided. The semiconductor support substrate 21 includes, for example, single crystal silicon.

The aberration compensation memory 117 stores the amount of axial chromatic aberration in the plane of the lens 2 and the imaging element 1. For example, the amount of axial chromatic aberration at the center and the periphery of the imaging element 1 is not constant, and varies from the center to the periphery. The amount of axial chromatic aberration is stored in the aberration compensation memory 117 for each image height for compensating for the variations. Furthermore, the amount of aberration may be stored for each area obtained by dividing a screen imaged by a storage capacity in the X direction (row direction) and Y direction (column direction), or alternatively, the lens 2 usually has the same characteristics from the center to the periphery (hereinafter, referred to as image height), so that the amount of aberration may be stored for each image height.

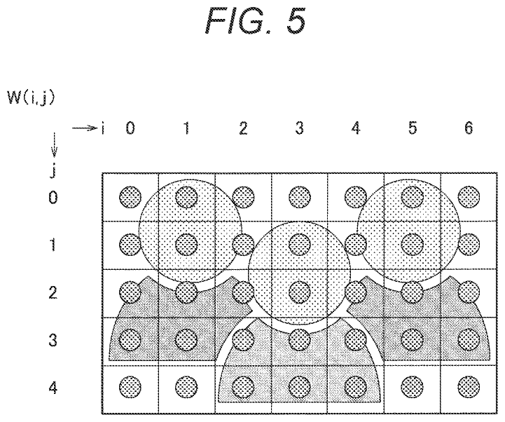

For example, FIG. 5 depicts an example where infrared light is output from the laser light source 4 in a pattern of six dots for X and four dots for Y, the angle of view is adjusted by the compensation lens 5, and the infrared light is applied to the subject OBJ, and the lens 2 of the imaging element 1 serves as a lens 2 adapted to the angle at which the infrared light is emitted, and visible light and the infrared light reflected off the subject OBJ are received by the imaging element 1. In this example, since the laser light source 4 has 24 dots of 6×4, it is only required that the area of the imaging element 1 be also divided into six areas for X and four areas for Y, and information (amount) of aberration to be described later of each area is stored.

In a case where the output of the laser light source 4 is emitted through the DOE or the like, the number of dots increases, so that the above-described X and Y areas in FIG. 5 may be increased, or alternatively, the information (amount) of aberration to be described later may be stored for each image height from the center.

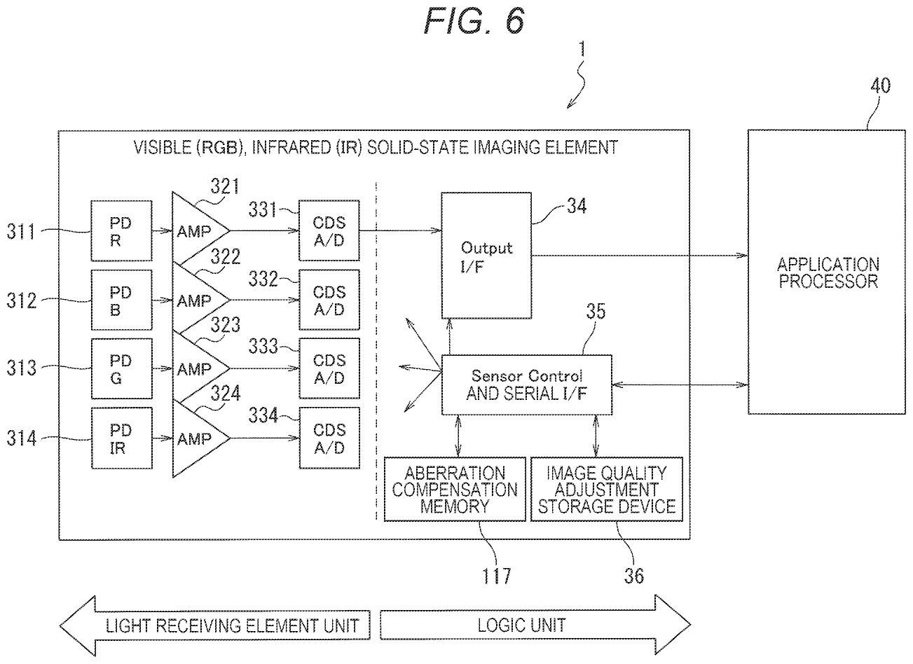

FIG. 6 depicts separate blocks corresponding to functions of the imaging element 1. The imaging element includes R, G, B color filters 26 for visible light, includes photodiodes (PDs) 311, 312, and 313 that each receive light of a corresponding light wavelength and a PD 314 that receives infrared light, and includes amplifiers 321, 322, 323, and 324 that each amplify an analog signal from a corresponding one of the PDs to a predetermined signal level, and a correlated double sampling (CDS) and A/D circuits 331, 332, 333, and 334 that each sample the analog signal amplified by a corresponding one of the amplifiers 321, 322, 323, 324 to convert the analog signal into a digital signal. Then, the imaging element 1 includes an output I/F circuit 34 for outputting the digital signal to an application processor 40 or the like locate outside. The output I/F circuit 34 has a function of receiving a control signal from the application processor 40 and passing the control details to a sensor control circuit 35 included in the imaging element 1. The sensor control circuit 35 is a circuit that controls a driving frequency, an exposure time, and the like of a sensor, and this circuit is a circuit having a function of reading necessary information from the aberration compensation memory 117 and an image quality adjustment storage device 36 included in the imaging element 1 and writing information to the aberration compensation memory 117 and the image quality adjustment storage device 36 as necessary.

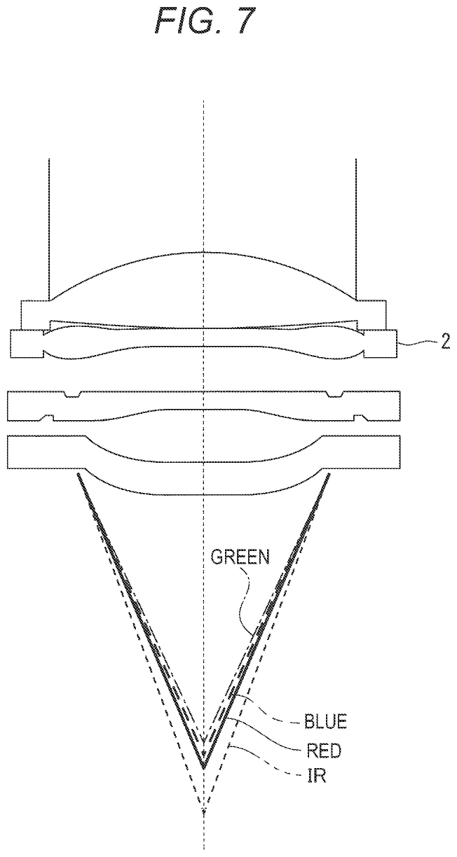

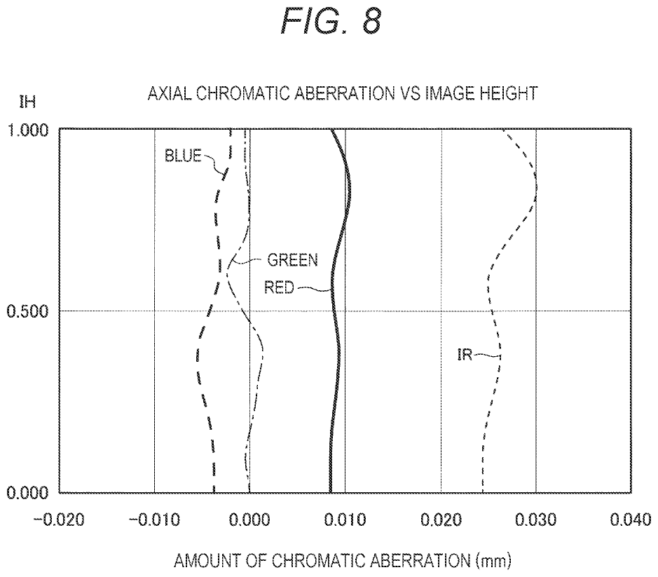

Next, compensation for aberration of the lens 2 in the imaging element 1 having the above-described functions will be described. FIG. 8 depicts an example of a graph showing a result of optical simulation of a focal position with the imaging element 1 as a target and a plurality of lenses in FIG. 7. The vertical axis represents an image height, and the horizontal axis represents a focal point of each light wavelength of red (R), green (G), blue (B), and infrared (IR). Red is indicated by a solid line in the drawing, green is indicated by a dashed line in the drawing, blue is indicated by a thick dotted line in the drawing, and infrared is indicated by a thin dotted line in the drawing.

As can be seen from FIG. 8, strictly speaking, R, G, B, and IR have different focal points, and for example, in a case where attention is paid to an image height 0 (IH 0.00), if the light wavelength of G is considered to be zero, blue deviates upward by 4 μm, red deviates downward by 8 μm, and infrared (IR) deviates downward by 24 μm relative to the imaging element surface. This is referred to as axial chromatic aberration.

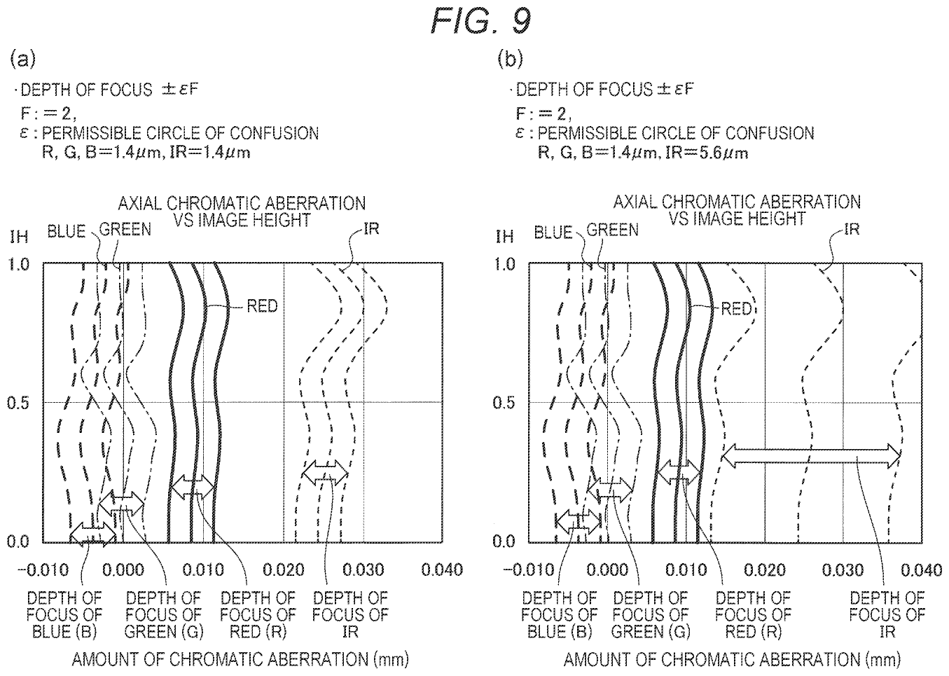

Here, FIG. 9(a) shows a depth of focus in a case where the size of the imaging element 1, that is, a circle size required for lens resolution (hereinafter, referred to as permissible circle of confusion) is 1.4 μm. and the lens has an F-number of 2, and the depth of focus is calculated by the following calculation expression:

Depth of focus=±εF (ε: permissible circle of confusion, F: F-number of lens).

A range between dotted lines in FIG. 9(a) indicates the depth of focus relative to a sensor surface, and even in view of the depth of focus, the focal points of G, R overlap with each other at an increase height 0 (IH 0.00), but R deviates even in consideration of the depth of focus, and it can be seen that IR greatly deviates.

FIG. 9(b) corresponds to an optical simulation example where an infrared light pixel to be described later includes an imaging element larger than an imaging element of a visible light pixel and shows a depth of focus in a case where the imaging element has a size of 1.4 μm, and the IR element has a size of 5.6 μm. As compared with FIG. 9(a), it can be seen that there is no change in depth of focus of R, G, B, but the depth of focus of IR increases. Even with such an imaging element, it can, however, be seen that the respective depths of focus of the light wavelengths do not coincide with each other.

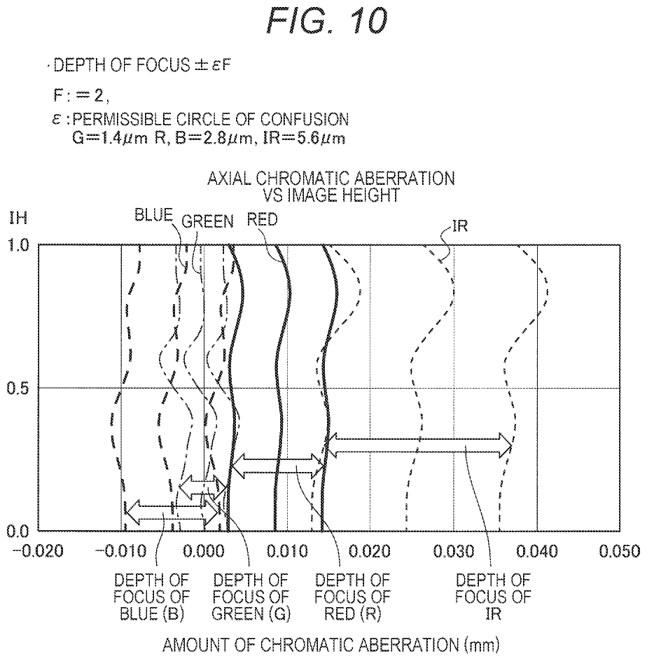

The above is the description of the case where the respective depths of focus of the light wavelengths do not coincide with each other unless an expensive lens is used such as an increase in the number of lens configurations or an increase in the lens configuration size. Here, the arrangement of the R, G, B color filters 26 of the imaging element 1 is typically a mosaic array generally called Bayer, and it is known that the number of elements arranged for the light wavelength of G is twice the number of R elements or B elements. Therefore, R and B need not be as high resolution as G, and it is generally calculated with a reciprocal of 2.8 μm in accordance with the number of elements. FIG. 10 is a graph with the permissible circle of confusion calculated with G=1.4 μm, R=B=2.8 μm, and IR=5.6 μm.

As described above with reference to FIGS. 9(a), 9(b), and 10, from such optical simulations and the like, in any of the cases, the depth of focus differs for each light wavelength due to the influence of axial chromatic aberration, and for example, when lens focus is adjusted on the basis of G, R and IR are out of focus, and conversely, when lens focus is adjusted on the basis of IR, R, G, and B are out of focus. Furthermore, in each drawing, it can be seen that details of the axial chromatic aberration vary in a manner that depends on the image height of the lens 2. This means that, for example, the focal point of the G pixel and the focal point of the IR deviate from each other at an image height 9 as compared with the image height 0 with the lens focus adjusted on the basis of the light wavelength of G.

### (Imaging Processing)

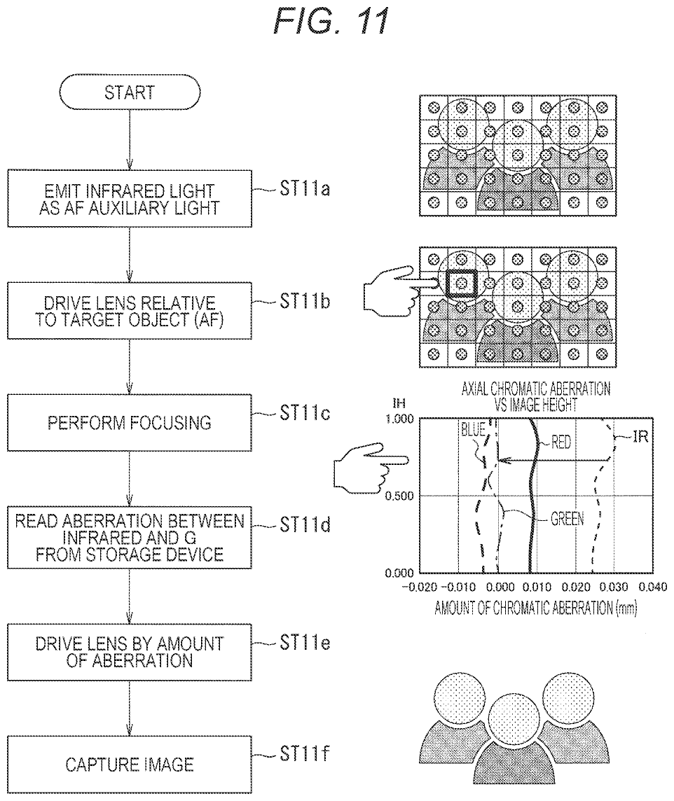

FIG. 11 is a flowchart depicting an example of a procedure of processing performed by the application processor 40 responsible for autofocusing and imaging in the imaging element 1.

First, the application processor 40 causes the laser light source 4 to emit infrared light to assist distance measurement or autofocusing (step ST11a). Then, the imaging element 1 captures an image of light reflected off the subject OBJ through the lens 2 and the DBPF 9. Normally, for the imaging element 1, such as a camera or a mobile terminal herein, the user designates the focus point of the subject, or the camera or the mobile terminal automatically designates the focus point in the imaging area.

Thereafter, the application processor 40 controls driving of the laser light source 4 to emit infrared light, drives the lens 2 by controlling the actuator 3 for focusing using a contrast, a phase difference, ToF, a structured light system, or the like (not described in detail), by using the light (in FIG. 11, for example, green light) reflected off the subject OBJ to perform autofocusing (step ST11b), and obtains focusing on the focal point of infrared light detected by the IR photoelectric conversion layer 23 of the imaging element 1 (step ST11c).

Since the autofocus position of the focused lens 2 described above is the focus point of the infrared light, the application processor 40 reads the amount of axial chromatic aberration stored in advance from the aberration compensation memory 117 (step ST11d), and controls the actuator 3 in accordance with the amount of aberration to move the lens 2 (step ST11e). Here, the difference in axial chromatic aberration is stored in the aberration compensation memory 117 for each image height, and the amount of aberration at the focus point, that is, the focus point in the imaging area can be used.

Then, the lens 2 is driven by the amount of aberration, and the imaging element 1 captures an image of visible light (step ST11f). At this time, the application processor 40 controls the imaging element 1 to capture an image of visible light.

### Effects Produced by First Embodiment

As described above, according to the first embodiment, the organic photoelectric conversion layer 25 for visible light and the IR photoelectric conversion layer 23 for infrared light (IR) are provided in the same semiconductor substrate 11 so as to be aligned with each other in the thickness direction, and the aberration compensation memory 117 storing the amount of aberration at a focal point between visible light and infrared light is provided in the semiconductor support substrate 21 of the semiconductor substrate 11. Therefore, a visible light image and an infrared light image can be simultaneously acquired at the same position on the imaging surface of the semiconductor substrate 11 of the imaging element 1, and moreover, a simple procedure of compensating for aberration at a focal point between visible light and infrared light after focusing using the amount of aberration stored in the aberration compensation memory 117 makes it possible to realize the imaging element 1 that allows an increase in performance, a reduction in size, and a reduction in cost while preventing a difference in focal point between visible light and infrared light.

Furthermore, according to the first embodiment, the actuator 3 drives the lens 2 in at least one of the X-axis direction (row direction) or the Y-axis direction (column direction) in response to camera shake, so that it is possible to compensate for camera shake.

Furthermore, according to the first embodiment, the amount of aberration is stored in the aberration compensation memory 117 for each image height at the position where the pixel P is provided or at the position of the pixel P, so that it is possible to compensate for aberration effectively in accordance with the image height even in a case where the aberration varies in a manner that depends on the image height.

Moreover, according to the first embodiment, since the visible light image and the infrared light image can be simultaneously acquired, the color of the subject OBJ can be determined, and an amount of aberration corresponding to the color of the subject OBJ is read from the aberration compensation memory 117 and is used to compensate for aberration at a focal point between light of the color component of the subject OBJ and infrared light, so that it is possible to capture an image that is suitably focused in a simple manner and short time.

Note that, according to the first embodiment, it is also possible to compensate for aberration at a focal point between the light of the color component of the subject OBJ and infrared light by controlling the actuator 3 to drive the lens 2 in the focus direction (Z-axis direction) in accordance with the amount of aberration corresponding to the color of the subject OBJ.

Note that the actuator 3 has a function of controlling in the X-axis direction (row direction) and the Y-axis direction (column direction) to compensate for camera shake caused by a photographer.

### First Modification of First Embodiment

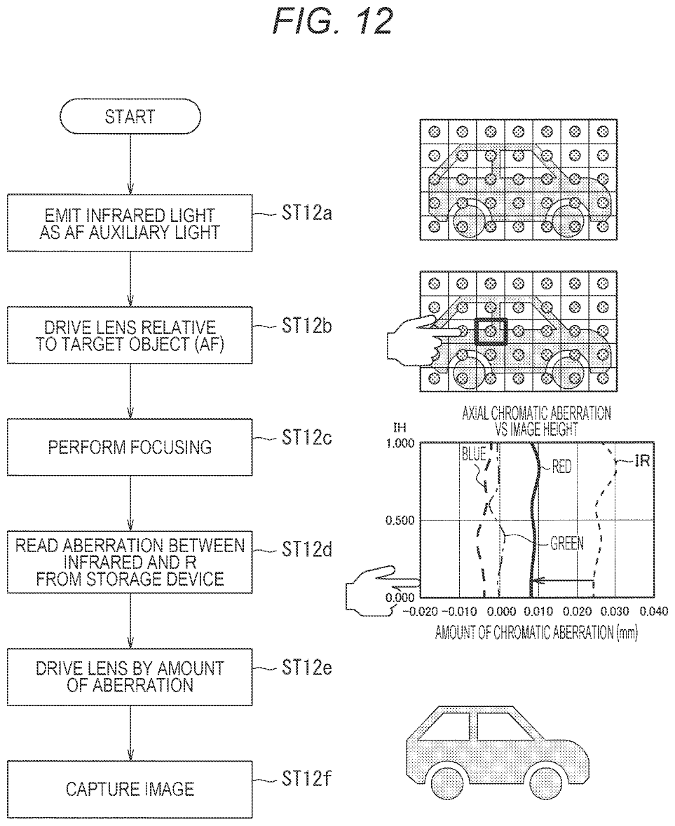

FIG. 12 is a flowchart depicting an example of a procedure of processing performed by an application processor 40 responsible for autofocusing and imaging in an imaging element 1 according to a first modification of the first embodiment.

For example, according to the first embodiment, the amount of axial chromatic aberration between the green light wavelength of visible light and infrared light is compensated for; however, the imaging element 1 can simultaneously capture an image of infrared light and an image of visible light, so that it is possible to determine the color of the subject. Here, according to the first modification, the subject OBJ is mainly occupied by the red light wavelength, and in this case, it is possible to capture an image suitably focused by using aberration between the red light wavelength and the infrared light wavelength.

First, the application processor 40 causes the laser light source 4 to emit infrared light to assist distance measurement or autofocusing (step ST12a). Then, the imaging element 1 captures an image of light reflected off the subject OBJ through the lens 2 and the DBPF 9.

Thereafter, the application processor 40 controls driving of the laser light source 4 to emit infrared light, drives the lens 2 by controlling the actuator 3 for focusing using a contrast, a phase difference, ToF, a structured light system, or the like (not described in detail), by using the light (in FIG. 12, for example, red light) reflected off the subject OBJ to perform autofocusing (step ST12b), and obtains focusing on the focal point of infrared light detected by the IR photoelectric conversion layer 23 of the imaging element 1 (step ST12c).

Since the autofocus position of the focused lens 2 described above is the focus point of the infrared light, the application processor 40 reads data on the amount of axial chromaticity stored in advance from the aberration compensation memory 117 (step ST12d), and controls the actuator 3 in accordance with the amount of aberration to move the lens 2 (step ST12e). Here, the difference in axial chromatic aberration is stored in the aberration compensation memory 117 for each image height, and the amount of aberration at the focus point, that is, the focus point in the imaging area can be used.

Then, the lens 2 is driven by the amount of aberration, and the imaging element 1 captures an image of visible light (step ST12f). At this time, the application processor 40 controls the imaging element 1 to capture an image of visible light.

### Effects Produced by First Modification of First Embodiment

As described above, the first modification of the first embodiment produces effects similar to the effects produced by the first embodiment described above.

### Second Modification of First Embodiment

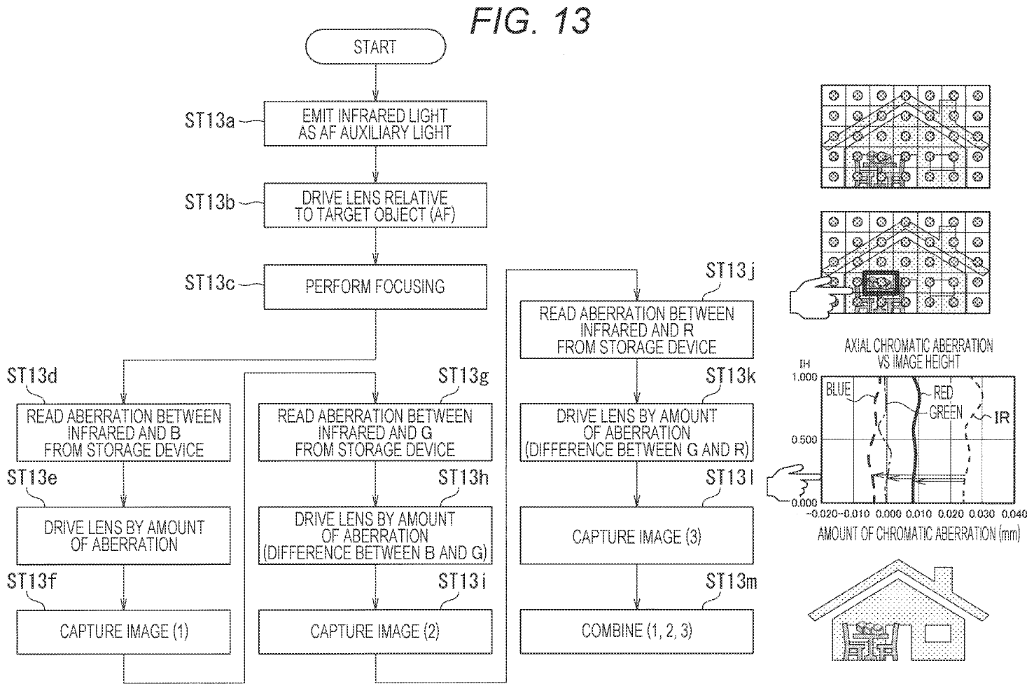

FIG. 13 is a flowchart depicting an example of a procedure of processing performed by an application processor 40 responsible for autofocusing and imaging in an imaging element 1 according to a second modification of the first embodiment.

For example, in the first embodiment described above, the amount of aberration between the green light wavelength of visible light and infrared light is used, and in the first modification of the first embodiment, the amount of aberration between the green light wavelength of visible light and infrared light is used, but in the second modification, compensation is performed using visible light data for all the stored amounts of aberration. In the second modification, from the depth of focus, blue visible light and green visible light largely overlap in depth with each other, but it can be seen that blue visible light and green visible light slightly deviate from an intended focus position. An overlap between red visible light and green visible light is small, so that an adjustment to the lens 2 in this overlapping portion requires high accuracy.

Therefore, in the second modification, an image of visible light, that is, an image of each visible light, and an image of infrared light are separately captured. First, the application processor 40 causes the laser light source 4 to emit infrared light to assist distance measurement or autofocusing (step ST13a). Then, the imaging element 1 captures an image of light reflected off the subject OBJ through the lens 2 and the DBPF 9.

Thereafter, the application processor 40 controls driving of the laser light source 4 to emit infrared light, drives the lens 2 by controlling the actuator 3 for focusing using a contrast, a phase difference, ToF, a structured light system, or the like (not described in detail), by using the light (in FIG. 13, for example, red light, green light, and blue light) reflected off the subject OBJ to perform autofocusing (step ST13b), and obtains focusing on the focal point of infrared light detected by the IR photoelectric conversion layer 23 of the imaging element 1 (step ST13c).

Since the autofocus position of the focused lens 2 described above is the focus point of the infrared light, the application processor 40 reads the amount of axial chromatic aberration between infrared light and blue light stored in advance from the aberration compensation memory 117 (step ST13d), and controls the actuator 3 in accordance with the amount of aberration to move the lens 2 (step ST13e). Here, the difference in axial chromatic aberration is stored in the aberration compensation memory 117 for each image height, and the amount of aberration at the focus point, that is, the focus point in the imaging area can be used.

Then, the lens 2 is driven by the amount of aberration, and the imaging element 1 captures an image of visible light, and outputs the resultant pixel signal (imaging data) to the application processor 40 (step ST13f). At this time, the application processor 40 controls the imaging element 1 to capture an image of visible light.

Next, the application processor 40 reads the amount of axial chromatic aberration between infrared light and green light stored in advance from the aberration compensation memory 117 (step ST13g), and controls the actuator 3 in accordance with the amount of aberration to move the lens 2 (step ST13h).

Then, the lens 2 is driven by the amount of aberration, and the imaging element 1 captures an image of visible light, and outputs the resultant pixel signal (imaging data) to the application processor 40 (step ST13j).

Next, the application processor 40 reads the amount of axial chromatic aberration between infrared light and red light stored in advance from the aberration compensation memory 117 (step ST13j), and controls the actuator 3 in accordance with the amount of aberration to move the lens 2 (step ST13k).

Then, the lens 2 is driven by the amount of aberration, and the imaging element 1 captures an image of visible light, and outputs the resultant pixel signal (imaging data) to the application processor 40 (step ST13l).

Thereafter, the application processor 40 combines the imaging data of blue light, the imaging data of green light, and the imaging data of red light output from the imaging element 1 (step ST13m).

In the second modification, since three times of imaging are required, the imaging element 1 is configured to output data on only blue pixels, only green pixels, or only red pixels for data volume reduction, thereby allowing a reduction in data volume.

Furthermore, the use of the method of the second modification makes it possible to perform, even with the lens 2 that is inexpensive and has axial chromatic aberration, imaging with all visible light focused although the imaging takes time.

Note that the first embodiment is an example where the amount of aberration between visible light of primary colors including red, green, and blue and infrared light is stored, but in a case of complementary colors, the color filter of the imaging element 1 may be adapted to, for example, yellow, purple, green, and magenta. Furthermore, in order to reduce the capacity of the aberration compensation memory 117, in comparison with lens performance, only one amount of aberration between visible light and infrared light may be stored.

That is, the present disclosure is characterized in that the imaging element 1 capable of simultaneously capturing an image of visible light and an image of infrared light regardless of color, at least one amount of aberration for each increase height between visible light and infrared light is stored, the lens 2 is driven to compensate for the amount of aberration, and suitable imaging is performed.

### Effects Produced by Second Modification of First Embodiment

As described above, according to the second modification of the first embodiment, even in a case where an inexpensive lens having axial chromatic aberration is used as the lens 2, it is possible to perform imaging with all visible light focused.

### Second Embodiment

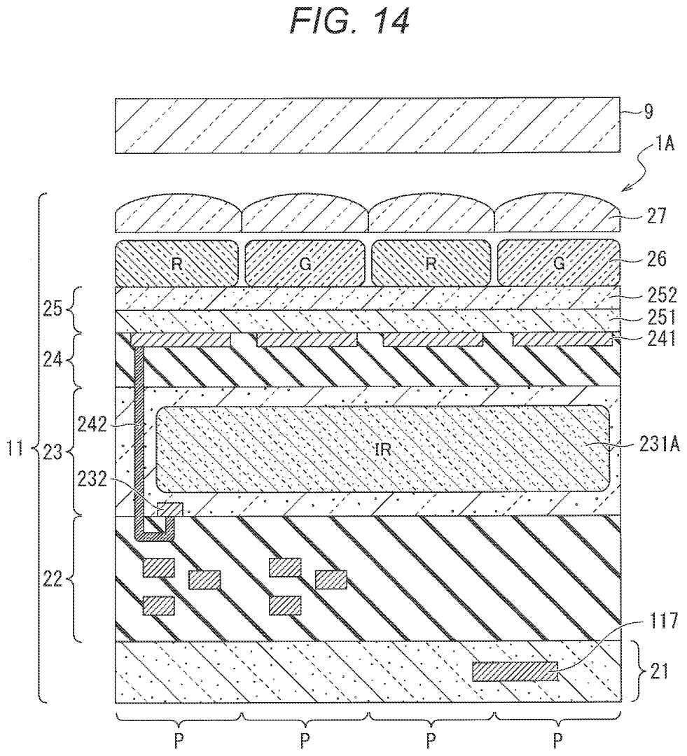

FIG. 14 is a partial longitudinal cross-sectional view depicting an example of a cross-sectional structure of a semiconductor substrate 11 of an imaging element 1A according to a second embodiment of the present disclosure. In FIG. 14, the same components as those in FIG. 4 described above are denoted by the same reference signs, and detailed description thereof is omitted.

The imaging element 1 according to the first embodiment and the imaging element 1A according to the second embodiment are different in configuration of a projector including the laser light source 4 and the compensation lens 5. For example, for a method called ToF by which infrared light emitted from the projector is applied as a specific pattern using an optical diffraction element or the like and distance measurement is performed in accordance with the shape of the pattern, a structure like the imaging element 1 is typically used. In the imaging element 1, the infrared light pixel and the visible light pixel, that is, an RGB pixel have the same size, and distance measurement using infrared light is the same in accuracy as distance measurement using visible pixel, so that high-accuracy focusing can be achieved.

In the second embodiment of the present disclosure, since the infrared light pixel (IR photoelectric conversion element 231A) has a size of a 4×4 visible light pixel P, so that the infrared light pixel is high in sensitivity, that is, capable of measuring a longer distance.

### Effects Produced by Second Embodiment

As described above, in the second embodiment, since the infrared light pixel (IR photoelectric conversion element 231A) has a size of a 4×4 visible light pixel P, so that the infrared light pixel is high in sensitivity, that is, capable of measuring a longer distance.

### Third Embodiment

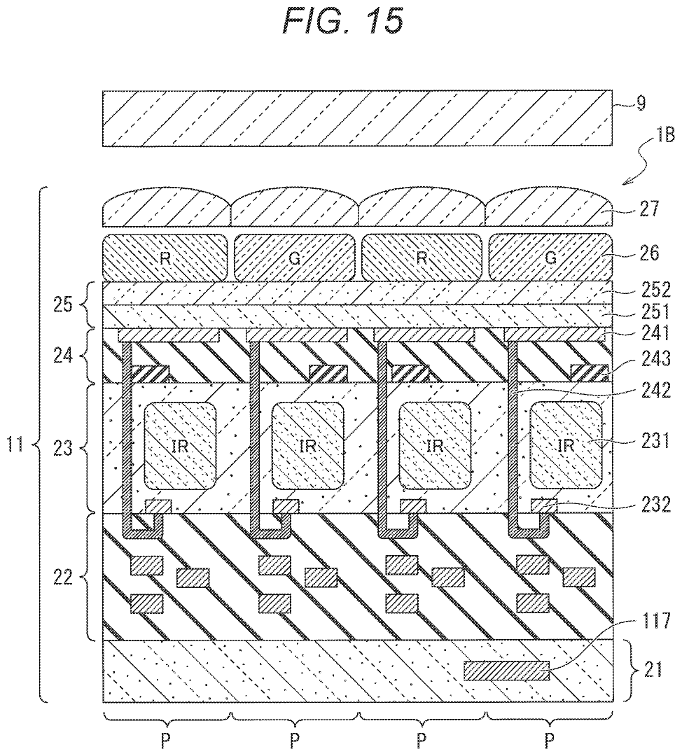

FIG. 15 is a partial longitudinal cross-sectional view depicting an example of a cross-sectional structure of a semiconductor substrate 11 of an imaging element 1B according to a third embodiment of the present disclosure. In FIG. 15, the same components as those in FIG. 4 described above are denoted by the same reference signs, and detailed description thereof is omitted.

In a case where infrared light from the above-described projector is used as auxiliary light, a structure where the infrared light pixel (IR photoelectric conversion element 231A) is capable of detecting a phase difference is effective. In the third embodiment of the present disclosure, a light shielding film 243 is provided for each visible light pixel P in the intermediate layer 24 to half-shield or divide the visible light pixel P to cause the visible light pixel P to serve as a phase difference pixel, thereby allowing distance measurement to be performed with both visible light and infrared light. Such a structure allows an increase in accuracy of distance measurement.

### Effects Produced by Third Embodiment

As described above, according to the third embodiment, the light shielding film 243 is provided for each visible light pixel P to cause the visible light pixel to serve as a phase difference pixel, thereby allowing distance measurement to be performed with both visible light and infrared light, and allows an increase in accuracy of distance measurement.

### Fourth Embodiment

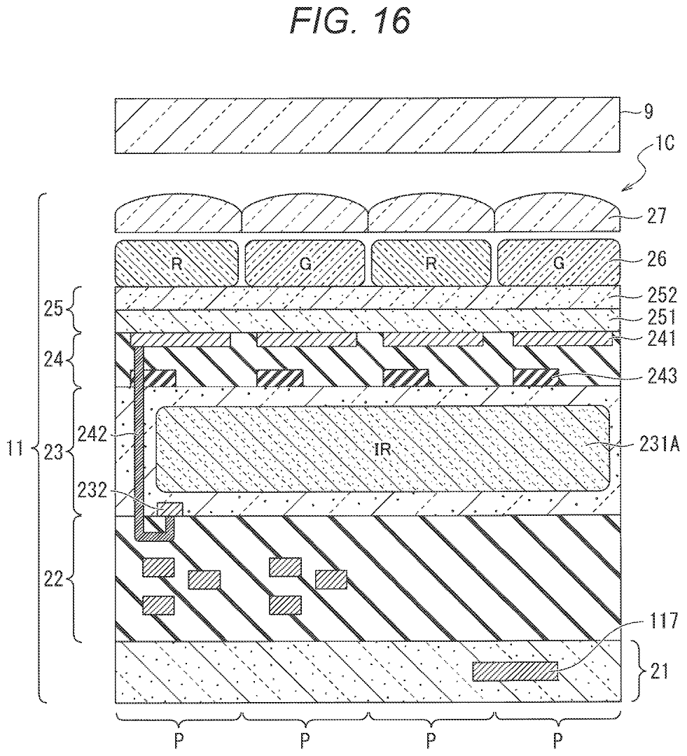

FIG. 16 is a partial longitudinal cross-sectional view depicting an example of a cross-sectional structure of a semiconductor substrate 11 of an imaging element 1C according to a fourth embodiment of the present disclosure. In FIG. 16, the same components as those in FIG. 14 described above are denoted by the same reference signs, and detailed description thereof is omitted.

In the fourth embodiment of the present disclosure, the light shielding film 243 is provided for each visible light pixel P in the intermediate layer 24 to half-shield or divide the visible light pixel P to cause the visible light pixel P to serve as a phase difference pixel, thereby allowing distance measurement to be performed with both visible light and infrared light.

### Effects Produced by Fourth Embodiment

As described above, the fourth embodiment produces effects similar to the effects produced by the second and third embodiments described above.

### Fifth Embodiment

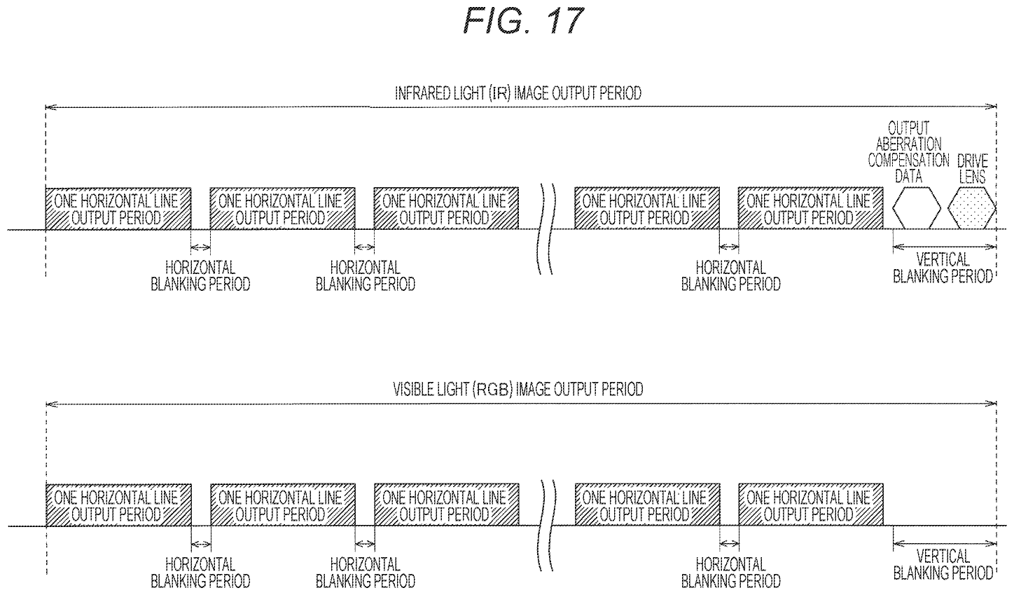

FIG. 17 depicts an example of how an imaging element 1 according to a fifth embodiment of the present disclosure outputs data. The imaging element 1 is responsible for distance measurement and autofocusing using infrared light. For this purpose, the imaging element 1 outputs data obtained by photoelectrically converting infrared light to an external device such as the application processor 40 through the output I/F circuit 34. The application processor 40 calculates a distance to the subject OBJ from the received infrared light imaging data, and drives the actuator 3 to perform autofocusing for focusing.

The imaging element 1 outputs the amount of aberration between infrared light and visible light stored in advance in the aberration compensation memory 117 as data to the application processor 40 through the output I/F circuit 34. The fifth embodiment of the present disclosure is an example of sequentially outputting an infrared light image output in a vertical blanking period of an imaging frame. The imaging frame is formed by a plurality of pixels P. In a case where the application processor 40 has a sufficient storage capacity, the amount of aberration stored in the imaging element 1 may be collectively transmitted and stored in a storage device of the application processor 40 when the imaging element 1 is powered on or when the entire device such as a mobile terminal is adjusted.

Upon receipt of the amount of aberration, the application processor 40 drives, for the next capturing of an image of visible light, the lens 2 in accordance with the amount of aberration to prepare for capturing of an image of visible light. The lens 2 is focused at a position in accordance with visible light, and the imaging element 1 outputs image data obtained by photoelectrically converting visible light to the application processor 40.

The fifth embodiment of the present disclosure is an example where infrared light and visible light are separately output, but in a case of a system where the accuracy of autofocusing is increased by determining focusing on the basis of image contrast with visible light, both infrared light and visible light may be output before and after focusing.

### Effects Produced by Fifth Embodiment

As described above, according to the fifth embodiment, causing the application processor 40 to perform control to read the amount of aberration on the aberration compensation memory 117 and control to drive the lens 2 on the actuator 3 using the vertical blanking period of the imaging frame of the infrared image makes it possible to compensate for aberration at a focal point between visible light and infrared light while performing processing of capturing the image of infrared light and the image of visible light and thus allows a reduction in imaging processing time.

Note that, in the fifth embodiment, an example where the vertical blanking period of the imaging frame of the infrared image is used has been described, but an example where a horizontal blanking period of the imaging frame of the infrared image is used can also be implemented.

### Other Embodiments

As described above, the present technology has been described by the first to fifth embodiments and the first and second modifications of the first embodiment, but it should not be understood that the description and drawings constituting a part of this disclosure limit the present technology. It will be apparent to those skilled in the art that various alternative embodiments, examples, and operation techniques may be included in the present technology when understanding the spirit of the technical content disclosed in the above-described first to fifth embodiments, and the first and second modifications of the first embodiment. Furthermore, the configurations disclosed in the first to fifth embodiments and the first and second modifications of the first embodiment can be appropriately combined within a range in which no contradiction occurs. For example, configurations disclosed in a plurality of different embodiments may be combined, or configurations disclosed in a plurality of different modifications of the same embodiment may be combined.

### Application Example to Photodetection System

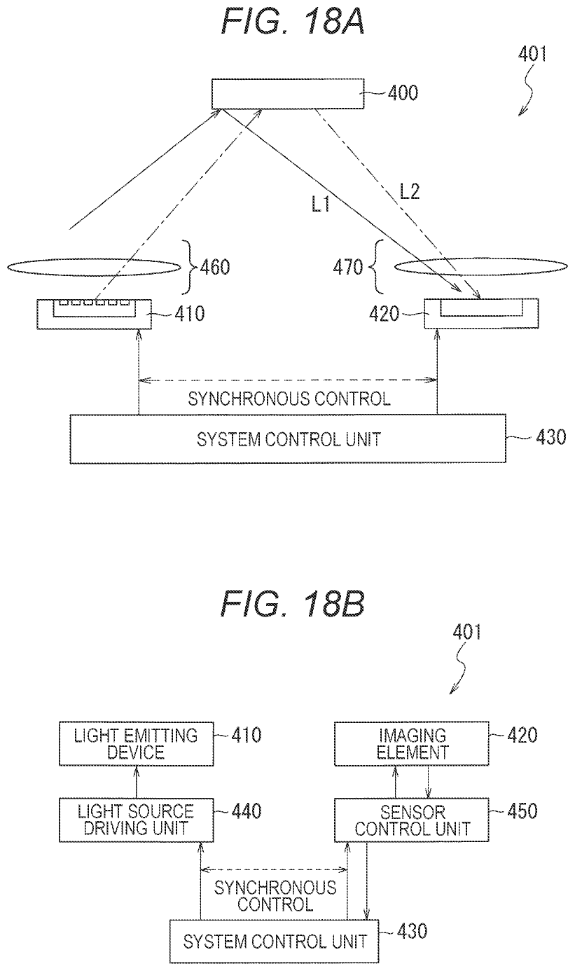

FIG. 18A is a schematic diagram depicting an example of an overall configuration of a photodetection system 401 according to a sixth embodiment of the present disclosure. FIG. 18B is a schematic diagram depicting an example of a circuit configuration of the photodetection system 401. The photodetection system 401 includes a light emitting device 410 serving as a light source unit that emits infrared light L2, and an imaging element 420 serving as a light receiving unit including a photoelectric conversion element. As the imaging element 420, the imaging element 1 described above can be used. The photodetection system 401 may further include a system control unit 430, a light source driving unit 440, a sensor control unit 450, a light source side optical system 460, and a camera side optical system 470.

The imaging element 420 can detect light L1 and light L2. The light L1 is light obtained when external ambient light is reflected off a subject (measurement target) 400 (FIG. 18A). The light L2 is light obtained when light emitted from light emitting device 410 is reflected off the subject 400. The light L1 is, for example, visible light, and the light L2 is, for example, infrared light. The light L1 can be detected by an organic photoelectric conversion unit in the imaging element 420, and the light L2 can be detected by a photoelectric conversion unit in the imaging element 420. Image information regarding the subject 400 can be obtained from the light L1, and distance information between the subject 400 and the photodetection system 401 can be obtained from the light L2. The photodetection system 401 can be mounted on, for example, an electronic device such as a smartphone or a mobile body such as a car. The light emitting device 410 can include, for example, a semiconductor laser, a surface emitting semiconductor laser, or a vertical cavity surface emitting laser (VCSEL). As a method for detecting the light L2 emitted from the light emitting device 410 with the imaging element 420, for example, an iTOF method can be employed, but the method is not limited to the iTOF method. The iTOF method allows the photoelectric conversion unit to measure a distance to the subject 400 on the basis of, for example, the time of flight (TOF). As a method for detecting the light L2 emitted from the light emitting device 410 with the imaging element 420, for example, a structured light method or a stereo vision method can also be employed. For example, the structured light method allows the distance between the photodetection system 401 and the subject 400 to be measured by projecting light of a predetermined pattern onto the subject 400 and analyzing a degree of distortion of the pattern. Furthermore, the stereo vision method allows the distance between the photodetection system 401 and the subject to be measured by acquiring two or more images of the subject 400 when viewed from two or more different viewpoints using, for example, two or more cameras. Note that the light emitting device 410 and the imaging element 420 can be synchronously controlled by the system control unit 430.

### Application Example to Electronic Device

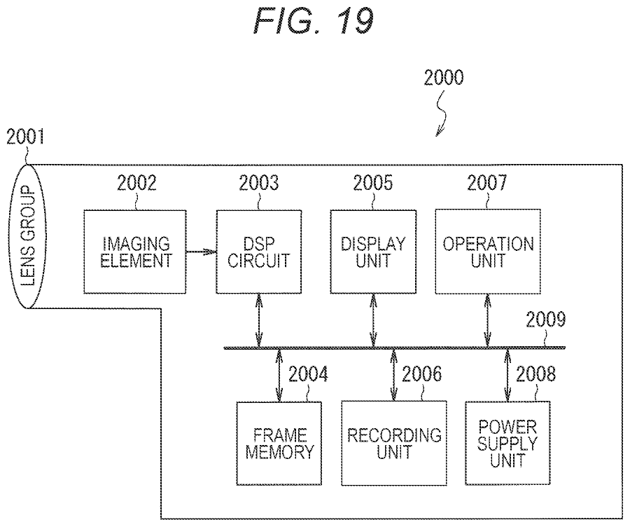

FIG. 19 is a block diagram depicting a configuration example of an electronic device 2000 to which the present technology is applied. The electronic device 2000 has a function as, for example, a camera.

The electronic device 2000 includes an optical unit 2001 including a lens group and the like, an imaging element 2002 to which the above-described imaging element 1 (hereinafter, referred to as imaging element 1 and the like) is applied, and a digital signal processor (DSP) circuit 2003 that is a camera signal processing circuit. Furthermore, the electronic device 2000 further includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are connected to one another over a bus line 2009.

The optical unit 2001 captures incident light (image light) from a subject, and forms an image on the imaging surface of the imaging element 2002. The imaging element 2002 converts the amount of the incident light the image of which is formed on the imaging surface by the optical unit 2001, into an electric signal on a pixel-by-pixel basis, and outputs the electric signal as a pixel signal.

The display unit 2005 includes, for example, a panel type display device such as a liquid crystal panel or an organic EL panel, and displays a moving image or a still image captured by the imaging element 2002. The recording unit 2006 records the moving image or the still image captured by the imaging element 2002 in a recording medium such as a hard disk or a semiconductor memory.

The operation unit 2007 issues operation commands for various functions of the electronic device 2000 under user operation. The power supply unit 2008 appropriately supplies various power sources serving as operation power sources of the DSP circuit 2003, the frame memory 2004, the display unit 2005, the recording unit 2006, and the operation unit 2007 to supply targets.

As described above, it can be expected to acquire a satisfactory image by using the above-described imaging element 1 and the like as the imaging element 2002.

### Application Example to Endoscopic Surgery System

The technology according to the present disclosure (the present technology) can be applied to various products. For example, the technology according to the present disclosure may be applied to an endoscopic surgery system.

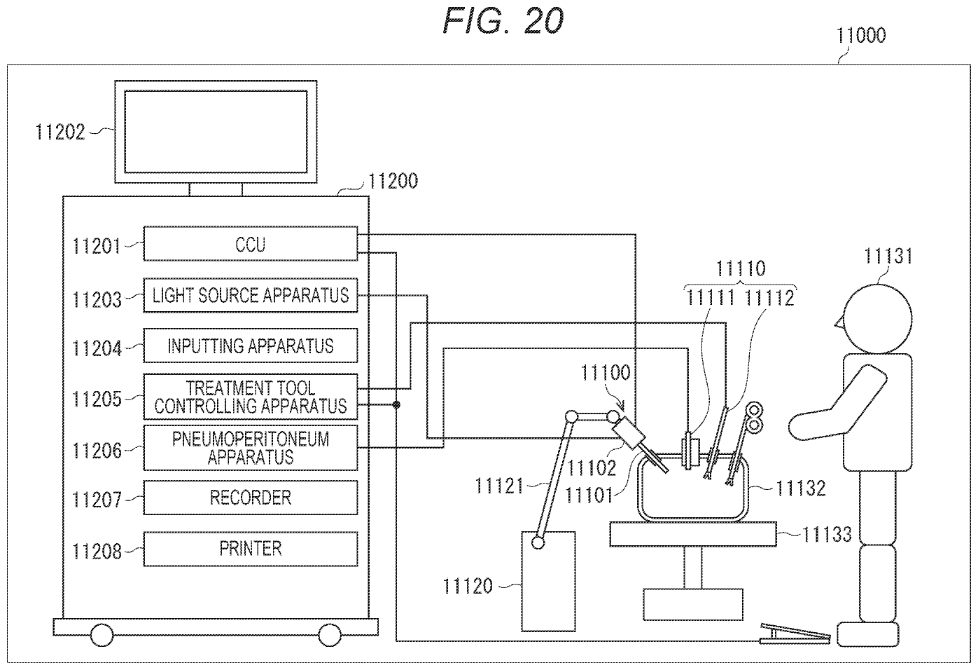

FIG. 20 is a view depicting an example of a schematic configuration of an endoscopic surgery system to which the technology according to an embodiment of the present disclosure (present technology) can be applied.

In FIG. 20, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

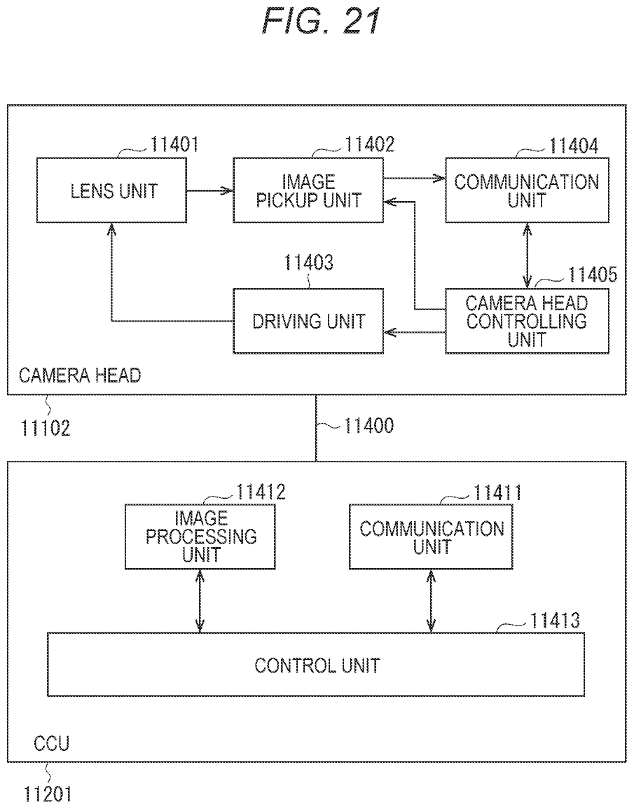

FIG. 21 is a block diagram depicting an example of a functional configuration of the camera head 11102 and the CCU 11201 depicted in FIG. 20.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the endoscope 11100, the image pickup unit 11402 of the camera head 11102, the image processing unit 11412 of the CCU 11201, and the like among the above-described configurations. Specifically, the imaging element 1 in FIG. 1 can be applied to an image pickup unit 10402.

Note that here, the endoscopic surgery system has been described as an example, but the technology according to the present disclosure may be applied to, for example, a microscopic surgery system or the like.

### Application Example to Mobile Body

The technology according to the present disclosure (the present technology) can be applied to various products. For example, the technology according to an embodiment of the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

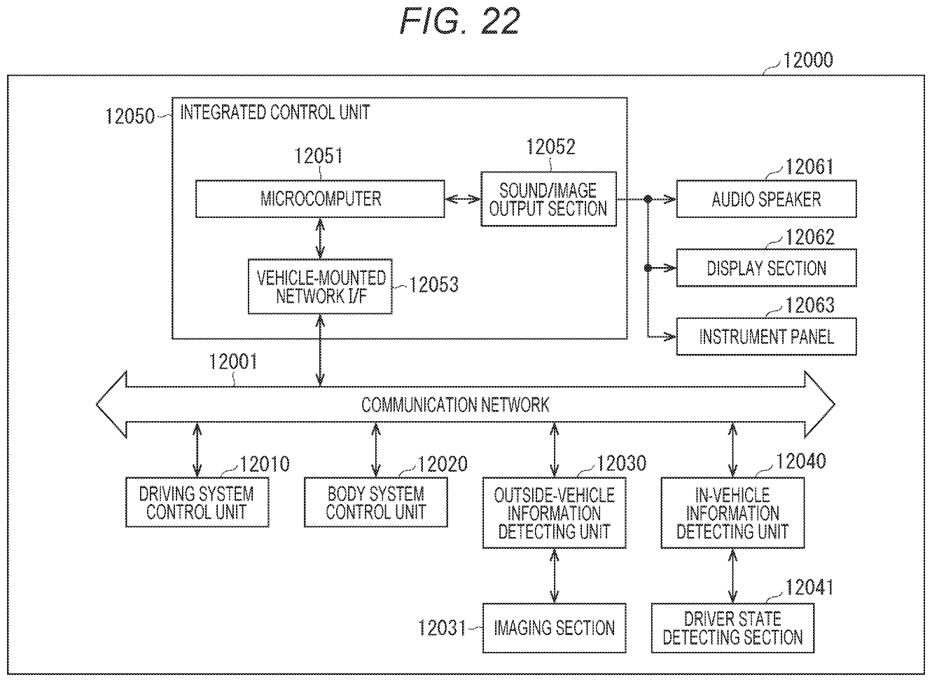

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 41, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information regarding the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 41, an audio speaker 12061, a display section 12062, and an instrument panel 12063 are illustrated as the output device. The display section 12062 may, for example, include at least one of an on-board display and a head-up display.

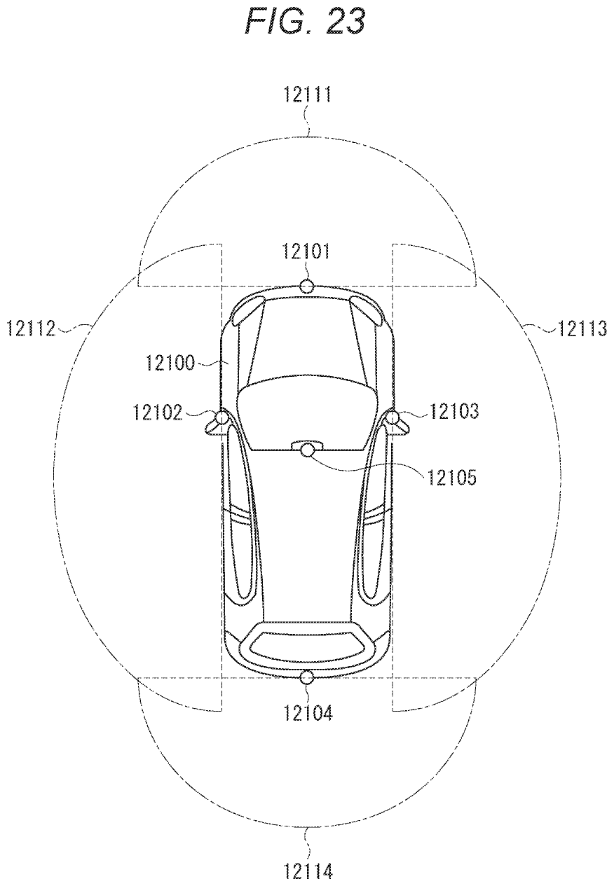

FIG. 23 is a diagram depicting an example of the installation position of the imaging section 12031.

In FIG. 23, a vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like, for example, among the components described above. Specifically, the technology can be applied to the imaging element 1 in FIG. 1.

Note that the present disclosure may also have the following configuration.

(1)

A solid-state imaging device including:
a lens optical system;
a first photoelectric conversion unit including a plurality of first photoelectric conversion elements provided in a matrix pattern, the plurality of first photoelectric conversion elements being configured to detect light in a first wavelength range including visible light reflected off a subject and perform photoelectric conversion;
a second photoelectric conversion unit provided at a position aligned with the first photoelectric conversion unit and including a plurality of second photoelectric conversion elements provided in a matrix pattern, the plurality of second photoelectric conversion elements being configured to detect light in a second wavelength range including infrared light reflected off the subject and perform photoelectric conversion; and
a storage unit configured to store an amount of aberration at a focal point between the light in the first wavelength range and the light in the second wavelength range in the lens optical system, in which
the aberration at a focal point between the light in the first wavelength range and the light in the second wavelength range is compensated for on the basis of the amount of aberration stored in the storage unit after focusing on a focal point of the light in the second wavelength range detected by the second photoelectric conversion unit.
   (2)

The solid-state imaging device according to the above (1), further including an optical filter provided on a side of the first photoelectric conversion unit remote from the second photoelectric conversion unit, the optical filter transmitting light of a predetermined color component that falls within a predetermined wavelength range.

(3)

The solid-state imaging device according to the above (1), further including
a driving unit configured to drive the lens optical system in at least one of a perspective direction relative to the subject, a row direction, or a column direction, the plurality of first photoelectric conversion elements and the plurality of second photoelectric conversion elements being provided in the row direction and the column direction, in which
the driving unit drives the lens optical system on the basis of the amount of aberration stored in the storage unit.
   (4)

The solid-state imaging device according to the above (3), in which
the driving unit drives the lens optical system in at least one of the row direction or the column direction in response to camera shake.
   (5)

The solid-state imaging device according to the above (1), in which
the storage unit is provided in a semiconductor substrate in which the first photoelectric conversion unit and the second photoelectric conversion unit are provided.
   (6)

The solid-state imaging device according to the above (1), in which
the storage unit stores the amount of aberration for each position where the first photoelectric conversion elements or the second photoelectric conversion elements are each provided or each image height at the position.
   (7)

The solid-state imaging device according to the above (1), in which
at least one of the first photoelectric conversion unit or the second photoelectric conversion unit includes a light shielding film for each of the first photoelectric conversion elements to serve as a phase difference pixel.
   (8)

The solid-state imaging device according to the above (1), further including
a driving unit configured to drive the lens optical system, in which
driving the lens optical system in accordance with the amount of aberration compensates for the aberration at a focal point between the light in the first wavelength range and the light in the second wavelength range.
   (9)

An imaging system including:
an irradiation unit configured to emit infrared light to a subject; and
an imaging element configured to receive light reflected off the subject, in which
the imaging element includes:
a lens optical system;
a first photoelectric conversion unit including a plurality of first photoelectric conversion elements provided in a matrix pattern, the plurality of first photoelectric conversion elements being configured to detect light in a first wavelength range including visible light reflected off the subject and perform photoelectric conversion;
a second photoelectric conversion unit provided at a position aligned with the first photoelectric conversion unit and including a plurality of second photoelectric conversion elements provided in a matrix pattern, the plurality of second photoelectric conversion elements being configured to detect light in a second wavelength range including infrared light reflected off the subject and perform photoelectric conversion; and
a storage unit configured to store an amount of aberration at a focal point between the light in the first wavelength range and the light in the second wavelength range in the lens optical system, and
the imaging element compensates for the aberration at a focal point between the light in the first wavelength range and the light in the second wavelength range on the basis of the amount of aberration stored in the storage unit after focusing on a focal point of the light in the second wavelength range detected by the second photoelectric conversion unit.
   (10)

The imaging system according to the above (9), further including
a signal processing unit configured to perform signal processing on the basis of an electric signal output for each of the first photoelectric conversion elements and an electric signal output for each of the second photoelectric conversion elements and perform read control on the storage unit, in which
the signal processing unit compensates for the aberration at a focal point between the light in the first wavelength range and the light in the second wavelength range on the basis of the amount of aberration stored in the storage unit after focusing on the focal point of the light in the second wavelength range detected by the second photoelectric conversion unit.
   (11)

The imaging system according to the above (9), further including an optical filter provided on a side of the first photoelectric conversion unit remote from the second photoelectric conversion unit, the optical filter transmitting light of a predetermined color component that falls within a predetermined wavelength range.

(12)

The imaging system according to the above (10), further including
a driving unit configured to drive the lens optical system in at least one of a perspective direction relative to the subject, a row direction, or a column direction, the plurality of first photoelectric conversion elements and the plurality of second photoelectric conversion elements being provided in the row direction and the column direction, in which
the driving unit drives, under drive control performed by the signal processing unit, the lens optical system on the basis of the amount of aberration stored in the storage unit.
   (13)

The imaging system according to the above (12), in which
the driving unit drives the lens optical system in at least one of the row direction or the column direction in response to camera shake.
   (14)

The imaging system according to the above (9), in which
the storage unit is provided in a semiconductor substrate in which the first photoelectric conversion unit and the second photoelectric conversion unit are provided.
   (15)

The imaging system according to the above (9), in which
the storage unit stores the amount of aberration for each position where the first photoelectric conversion elements or the second photoelectric conversion elements are each provided or each image height at the position.
   (16)

The imaging system according to the above (9), in which
at least one of the first photoelectric conversion unit or the second photoelectric conversion unit includes a light shielding film for each of the first photoelectric conversion elements to serve as a phase difference pixel.
   (17)

The imaging system according to the above (10), in which
the signal processing unit compensates for aberration at a focal point between light of at least one color component included in the visible light and the infrared light on the basis of the amount of aberration stored in the storage unit.
   (18)

The imaging system according to the above (10), in which
the signal processing unit sequentially compensates for aberration at a focal point between light of at least three color components included in the visible light and the infrared light on the basis of the amount of aberration stored in the storage unit.
   (19)

The imaging system according to the above (12), in which
the signal processing unit compensates for the aberration at a focal point by controlling the driving unit to drive the lens optical system on the basis of the amount of aberration stored in the storage unit.
   (20)

The imaging system according to the above (12), in which
for an imaging frame formed by the plurality of first photoelectric conversion elements or the plurality of second photoelectric conversion elements, the signal processing unit performs the read control on the storage unit and the drive control of the lens optical system on the driving unit in a blanking period of the imaging frame.
   (21)

An imaging processing method including:
causing an irradiation unit to emit infrared light to a subject;
causing a signal processing unit to drive a lens optical system relative to the subject on the basis of light reflected off the subject to focus on a focal point of light in a first wavelength range including the infrared light; and
causing the signal processing unit to read an amount of aberration stored in a storage unit on the basis of a result of focusing on the focal point of the light in the first wavelength range and compensate for aberration at a focal point between light in a second wavelength range including visible light and the light in the first wavelength range on the basis of the amount of aberration.

### REFERENCE SIGNS LIST

1, 1A, 1B, 1C Imaging element
2 Lens
3 Actuator
4 Laser light source
5 Compensation lens
7 Gyro sensor
8 Circuit board
9 Dual-bandpass filter (DBPF)
10 Sensor system
11 Semiconductor substrate
21 Semiconductor support substrate
22 Wiring layer
23 IR photoelectric conversion layer
24 Intermediate layer
25 Organic photoelectric conversion layer
26 Color filter
27 On-chip lens
31 Metal wire
32 Adhesive
34 Output I/F circuit
35 Sensor control circuit
36 Image quality adjustment storage device
40 Application processor
100 Pixel unit
111 Vertical drive circuit
112 Column signal processing circuit
113 Horizontal drive circuit
114 Output circuit
115 Control circuit
116 Input/output terminal
117 Aberration compensation memory
121 Horizontal signal line
231, 231A IR photoelectric conversion element
232 Electrode
241 Electrode
242 Wiring
243 Light shielding film
251, 252 Organic photoelectric conversion element
311, 312, 313, 314 Photodiode (PD)
321, 322, 323, 324 Amplifier
331, 332, 333, 334 CDS and A/D circuit
400 Subject (measurement target)
401 Photodetection system
410 Light emitting device
420 Imaging element
430 System control unit
440 Light source driving unit
450 Sensor control unit
460 Light source side optical system
470 Camera side optical system
2000 Electronic device
2001 Optical unit
2002 Imaging element
2003 DSP circuit
2003 (Digital signal processor) circuit
2004 Frame memory
2005 Display unit
2006 Recording unit
2007 Operation unit
2008 Power supply unit
2009 Bus line
10402 Image pickup unit
11000 Endoscopic surgery system
11100 Endoscope
11101 Lens barrel
11102 Camera head
11110 Surgical tool
11111 Pneumoperitoneum tube
11112 Energy device
11120 Supporting arm apparatus
11131 Surgeon (medical doctor)
11131 Surgeon
11132 Patient
11133 Patient bed
11200 Cart
11201 Camera control unit (CCU)
11202 Display apparatus
11203 Light source apparatus
11204 Inputting apparatus
11205 Treatment tool controlling apparatus
11206 Pneumoperitoneum apparatus
11207 Recorder
11208 Printer
11400 Transmission cable
11401 Lens unit
11402 Image pickup unit
11403 Driving unit
11404 Communication unit
11405 Camera head controlling unit
11411 Communication unit
11412 Image processing unit
11413 Control unit
12000 Vehicle control system
12001 Communication network
12010 Driving system control unit
12020 Body system control unit
12030 Outside-vehicle information detecting unit
12031 Image pickup unit
12040 In-vehicle information detecting unit
12041 Driver state detecting section
12050 Integrated control unit
12051 Microcomputer
12052 Sound/image output section
12061 Audio speaker
12062 Display unit
12063 Instrument panel
12100 Vehicle
12101, 12102, 12103, 12104, 12105 Image pickup unit
12111, 12112, 12113, 12114 Imaging range

1. A solid-state imaging device comprising:
a lens optical system;
a first photoelectric conversion unit including a plurality of first photoelectric conversion elements provided in a matrix pattern, the plurality of first photoelectric conversion elements being configured to detect light in a first wavelength range including visible light reflected off a subject and perform photoelectric conversion;
a second photoelectric conversion unit provided at a position aligned with the first photoelectric conversion unit and including a plurality of second photoelectric conversion elements provided in a matrix pattern, the plurality of second photoelectric conversion elements being configured to detect light in a second wavelength range including infrared light reflected off the subject and perform photoelectric conversion; and
a storage unit configured to store an amount of aberration at a focal point between the light in the first wavelength range and the light in the second wavelength range in the lens optical system, wherein
the aberration at a focal point between the light in the first wavelength range and the light in the second wavelength range is compensated for on a basis of the amount of aberration stored in the storage unit after focusing on a focal point of the light in the second wavelength range detected by the second photoelectric conversion unit.

2. The solid-state imaging device according to claim 1, further comprising
an optical filter provided on a side of the first photoelectric conversion unit remote from the second photoelectric conversion unit, the optical filter transmitting light of a predetermined color component that falls within a predetermined wavelength range.

3. The solid-state imaging device according to claim 1, further comprising
a driving unit configured to drive the lens optical system in at least one of a perspective direction relative to the subject, a row direction, or a column direction, the plurality of first photoelectric conversion elements and the plurality of second photoelectric conversion elements being provided in the row direction and the column direction, wherein
the driving unit drives the lens optical system on a basis of the amount of aberration stored in the storage unit.

4. The solid-state imaging device according to claim 3, wherein
the driving unit drives the lens optical system in at least one of the row direction or the column direction in response to camera shake.

5. The solid-state imaging device according to claim 1, wherein
the storage unit is provided in a semiconductor substrate in which the first photoelectric conversion unit and the second photoelectric conversion unit are provided.

6. The solid-state imaging device according to claim 1, wherein
the storage unit stores the amount of aberration for each position where the first photoelectric conversion elements or the second photoelectric conversion elements are each provided or each image height at the position.

7. The solid-state imaging device according to claim 1, wherein
at least one of the first photoelectric conversion unit or the second photoelectric conversion unit includes a light shielding film for each of the first photoelectric conversion elements to serve as a phase difference pixel.

8. The solid-state imaging device according to claim 1, further comprising
a driving unit configured to drive the lens optical system, wherein
driving the lens optical system in accordance with the amount of aberration compensates for the aberration at a focal point between the light in the first wavelength range and the light in the second wavelength range.

9. An imaging system comprising:
an irradiation unit configured to emit infrared light to a subject; and
an imaging element configured to receive light reflected off the subject, wherein
the imaging element includes:
a lens optical system;
a first photoelectric conversion unit including a plurality of first photoelectric conversion elements provided in a matrix pattern, the plurality of first photoelectric conversion elements being configured to detect light in a first wavelength range including visible light reflected off the subject and perform photoelectric conversion;
a second photoelectric conversion unit provided at a position aligned with the first photoelectric conversion unit and including a plurality of second photoelectric conversion elements provided in a matrix pattern, the plurality of second photoelectric conversion elements being configured to detect light in a second wavelength range including infrared light reflected off the subject and perform photoelectric conversion; and
a storage unit configured to store an amount of aberration at a focal point between the light in the first wavelength range and the light in the second wavelength range in the lens optical system, and
the imaging element compensates for the aberration at a focal point between the light in the first wavelength range and the light in the second wavelength range on a basis of the amount of aberration stored in the storage unit after focusing on a focal point of the light in the second wavelength range detected by the second photoelectric conversion unit.

10. The imaging system according to claim 9, further comprising
a signal processing unit configured to perform signal processing on a basis of an electric signal output for each of the first photoelectric conversion elements and an electric signal output for each of the second photoelectric conversion elements and perform read control on the storage unit, wherein
the signal processing unit compensates for the aberration at a focal point between the light in the first wavelength range and the light in the second wavelength range on a basis of the amount of aberration stored in the storage unit after focusing on the focal point of the light in the second wavelength range detected by the second photoelectric conversion unit.

11. The imaging system according to claim 9, further comprising
an optical filter provided on a side of the first photoelectric conversion unit remote from the second photoelectric conversion unit, the optical filter transmitting light of a predetermined color component that falls within a predetermined wavelength range.

12. The imaging system according to claim 10, further comprising
a driving unit configured to drive the lens optical system in at least one of a perspective direction relative to the subject, a row direction, or a column direction, the plurality of first photoelectric conversion elements and the plurality of second photoelectric conversion elements being provided in the row direction and the column direction, wherein
the driving unit drives, under drive control performed by the signal processing unit, the lens optical system on a basis of the amount of aberration stored in the storage unit.

13. The imaging system according to claim 12, wherein
the driving unit drives the lens optical system in at least one of the row direction or the column direction in response to camera shake.

14. The imaging system according to claim 9, wherein
the storage unit is provided in a semiconductor substrate in which the first photoelectric conversion unit and the second photoelectric conversion unit are provided.

15. The imaging system according to claim 9, wherein
the storage unit stores the amount of aberration for each position where the first photoelectric conversion elements or the second photoelectric conversion elements are each provided or each image height at the position.

16. The imaging system according to claim 9, wherein
at least one of the first photoelectric conversion unit or the second photoelectric conversion unit includes a light shielding film for each of the first photoelectric conversion elements to serve as a phase difference pixel.

17. The imaging system according to claim 10, wherein
the signal processing unit compensates for aberration at a focal point between light of at least one color component included in the visible light and the infrared light on a basis of the amount of aberration stored in the storage unit.

18. The imaging system according to claim 10, wherein
the signal processing unit sequentially compensates for aberration at a focal point between light of at least three color components included in the visible light and the infrared light on a basis of the amount of aberration stored in the storage unit.

19. The imaging system according to claim 12, wherein
the signal processing unit compensates for the aberration at a focal point by controlling the driving unit to drive the lens optical system on a basis of the amount of aberration stored in the storage unit.

20. The imaging system according to claim 12, wherein
for an imaging frame formed by the plurality of first photoelectric conversion elements or the plurality of second photoelectric conversion elements, the signal processing unit performs the read control on the storage unit and the drive control of the lens optical system on the driving unit in a blanking period of the imaging frame.

21. An imaging processing method comprising:
causing an irradiation unit to emit infrared light to a subject;
causing a signal processing unit to drive a lens optical system relative to the subject on a basis of light reflected off the subject to focus on a focal point of light in a first wavelength range including the infrared light; and
causing the signal processing unit to read an amount of aberration stored in a storage unit on a basis of a result of focusing on the focal point of the light in the first wavelength range and compensate for aberration at a focal point between light in a second wavelength range including visible light and the light in the first wavelength range on a basis of the amount of aberration.
